(19) United States
(12) Patent Application Publication
(10) Pub. No.: US 2026/0282344 A1
(43) Pub. Date: Sep. 17, 2026

(54) PITCH INTERFACE LAYER INCLUDING MEMORY CELL CONTROL CIRCUITRY COMPONENTS IN THREE-DIMENSIONAL MEMORY

(71) Applicant: Micron Technology, Inc., Boise, ID (US)

(72) Inventors: David A. Daycock, Boise, ID (US); Scott E. Sills, Boise, ID (US); Mingdong Cui, Folsom, CA (US); Murali Balakrishnan, Boise, ID (US); Durai Vishak Nirmal Ramaswamy, Boise, ID (US)

(21) Appl. No.: 19/179,117

(22) Filed: Apr. 15, 2025

Related U.S. Application Data
(60) Provisional application No. 63/650,593, filed on May 22, 2024.

(51) Int. Cl. H10B 12/00; H10B 80/00; H10W 90/00; H10W 90/26

(52) U.S. Cl. CPC H10B 12/50; H10B 12/30; H10B 80/00; H10W 90/26; H10W 90/792

(57) ABSTRACT

Systems, methods, and apparatus are provided for memory devices having memory cell control circuitry connected to memory arrays by a pitch interface layer. The memory cell control circuitry can include a first portion of memory cell control circuitry components including complementary metal oxide semiconductor (CMOS) logic and including device input/output (I/O) connections. The memory array can have a three-dimensional (3D) dynamic random access memory (DRAM) cell structure having horizontally oriented, vertically stacked memory cells. The pitch interface layer can have a second portion of memory cell control circuitry components and electrically connect the memory cell control circuitry to the memory array in a face to face (F2F) orientation to distribute array efficiency (AE), to increase wafer usage density, and/or to reduce component to component electrical connection constraints.

### PRIORITY INFORMATION

This application claims the benefit of U.S. Provisional Application Number 63/650,593, filed on May 22, 2024, the contents of which are incorporated herein by reference.

### TECHNICAL FIELD

The present disclosure relates generally to memory devices, and more particularly, to a pitch interface layer including memory cell control circuitry components in three-dimensional (3D) memory.

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like.

As design rules shrink, less semiconductor space is available to fabricate memory, including DRAM arrays. A respective memory cell for DRAM may include an access device, e.g., transistor, having a first and a second source/drain region separated by a channel region. A gate may oppose the channel region and be separated therefrom by a gate dielectric. An access line, such as a word line, is electrically connected to the gate of the DRAM memory cell. A DRAM memory cell can include a storage node, such as a capacitor cell, electrically connected by the access device to a sense line, such as a digit line. The access device can be activated (e.g., to select the cell) by an access line electrically connected to the access device. The capacitor can store a charge corresponding to a data value of a respective memory cell (e.g., a logic “1” or “0”).

### BRIEF DESCRIPTION OF THE DRAWINGS

FIG. 1A is a schematic illustration of an array of memory cells in a vertical three dimensional (3D) memory combinable with pitch interface layers in accordance with a number of embodiments of the present disclosure.

FIG. 1B is a perspective view illustrating a portion of horizontal access devices in vertical three dimensional (3D) memory combinable with pitch interface layers in accordance with a number of embodiments of the present disclosure.

FIG. 2 illustrates a portion of a horizontal access devices in vertical three dimensional (3D) memory combinable with pitch interface layers in accordance with a number of embodiments of the present disclosure.

FIG. 3A is a schematic illustration, in vertical orientation, of complementary metal oxide semiconductor (CMOS) logic in functional association with memory arrays for use with pitch interface layers in accordance with a number of embodiments of the present disclosure.

FIG. 3B illustrates an example embodiment of pitch interface layers for three-dimensional memory in accordance with a number of embodiments of the present disclosure.

FIG. 4 is a perspective view illustrating an example embodiment of a three-dimensional (3D) dynamic random access memory (DRAM) cell structure of horizontally oriented, vertically stacked memory cells in a plurality of levels, combinable with pitch interface layers in accordance with a number of embodiments of the present disclosure.

FIG. 5 is a cross-sectional view of an example method, at one stage of a semiconductor fabrication process, for forming a three-dimensional (3D) dynamic random access memory (DRAM) cell structure of horizontally oriented, vertically stacked memory cells in a plurality of levels combinable with pitch interface layers in accordance with a number of embodiments of the present disclosure.

FIGS. 6A to 6B illustrate an example method, at one stage of a semiconductor fabrication process, for forming 3D DRAM arrays combinable with pitch interface layers, in accordance with a number of embodiments of the present disclosure.

FIGS. 7A to 7D illustrate an example method, at another stage of a semiconductor fabrication process, for forming 3D DRAM arrays combinable with pitch interface layers, in accordance with a number of embodiments of the present disclosure.

FIGS. 8A to 8B illustrate an example method, at another stage of a semiconductor fabrication process, for forming 3D DRAM arrays combinable with pitch interface layers, in accordance with a number of embodiments of the present disclosure.

FIG. 9 illustrates an example method, at another stage of a semiconductor fabrication process, for forming 3D DRAM arrays combinable with pitch interface layers, in accordance with a number of embodiments of the present disclosure.

FIGS. 10A to 10C illustrate an example method, at another stage of a semiconductor fabrication process, for forming 3D DRAM arrays combinable with pitch interface layers, in accordance with a number of embodiments of the present disclosure.

FIG. 11 is a block diagram of an apparatus in the form of a computing system including a memory device in accordance with a number of embodiments of the present disclosure.

### DETAILED DESCRIPTION

Embodiments of the present disclosure describe pitch interface layers for three-dimensional memory. Embodiments are provided for memory devices having memory cell control circuitry connected to a memory array by logic formed on a pitch interface layer. The memory cell control circuitry can include a first portion of memory cell control circuitry components, for operation and control of memory arrays, including complementary metal oxide semiconductor (CMOS) logic and including device input/output (I/O) connections. The memory wafer can have a three-dimensional (3D) dynamic random access memory (DRAM) cell structure having horizontally oriented, vertically stacked memory cells in a plurality of levels. The pitch interface layer can have a second portion of memory cell control circuitry components, for operation and control of memory arrays, and can electrically connect the memory cell control circuitry to the memory wafer in a face to face (F2F) orientation to distribute array efficiency (AE), to increase wafer usage density, and/or to reduce wafer to wafer electrical connection constraints.

According to embodiments, in the three-dimensional (3D) dynamic random access memory (DRAM) cell structure having horizontally oriented, vertically stacked memory cells in a plurality of levels, a vertically oriented sense line (e.g., digit line) can be formed electrically connected to first source/drain regions of horizontally oriented access devices. Horizontally oriented access lines can be formed and serve as gates opposing channel regions of the horizontally oriented access devices, separated therefrom by gate dielectric material. The channel regions separate first source/drain regions and second source/drain regions for the horizontally oriented access devices. Horizontally oriented storage nodes, e.g., capacitors, can be formed at each level, electrically coupled independently to the second source/drain regions of the horizontally oriented access devices in an array of vertically stacked memory cells.

Functional logic, e.g., in the form of complementary metal oxide semiconductor (CMOS) logic, is associated with the memory array to control operation and access. Functional logic can include, for example: input/output (I/O) connections to a memory die; sense amplifiers (SAs) for sensing, e.g., reading, sense lines, e.g., digit lines (DLs); digit line multiplexers (DLMUXs) for independently accessing particular digit lines in an array; sub-access line (e.g., wordline) drivers (SWDs), etc. Embodiments are not limited to the examples given herein. In some memory device embodiments, functional logic is formed separately and upon a separate semiconductor wafer, e.g., separate silicon (Si) wafer to form a memory cell control circuitry, e.g., complementary metal oxide semiconductor (CMOS) wafer, and then mechanically and electrically joined to a memory array, e.g., mechanically (physically) bonded together and electrical connections formed therebetween to complete appropriate circuit interconnections in a semiconduction fabrication process. In some approaches memory cell control circuitry sis bonded and electrically connected to memory arrays in a face to back (F2B) orientation. For example, a “face” to a completed memory array wafer may be bonded to a “back” of a completed memory cell control circuitry wafer. In this example, electrical connections from the uppermost surface, e.g., “face”, of the memory wafer have to be formed through the back of the memory cell control circuitry to the appropriate functional circuit connections formed above, in a vertical orientation, on the memory cell control circuitry. Herein a “face” is intended to mean and “uppermost” completed surface in a vertical orientation resulting from a semiconductor formation and fabrication process on a substrate, whether memory or logic components and/or circuitry are being formedthereon. Conversely, a “back” is intended to mean a “lowermost”, starting structure and/or components from a substrate upon which the formation and fabrication process is performed resulting in layers of memory cells in a memory array in a memory array or logic components and/or circuitry for logic functionality formed thereon as memory cell control circuitry, e.g., CMOS wafer.

In a F2B memory array to memory cell control circuitry approach, the complexity of bonding and forming appropriate electrical connections from the “face” of the memory array, through the “back” of memory cell control circuitry becomes more challenging as the design rules shrink and array density, array efficiency (AE), and die size efficiency demands increase, potentially resulting in an increase to process sequencing complexity and potentially reducing alignment variation tolerance.

Further, as design rules shrink and circuit and component size may differ between memory cell control circuitry, e.g., memory logic, and memory arrays, the “face” to “face” (F2F) memory array to memory cell control circuitry connection may ease alignment tolerances relative to mechanical (physical) bonding challenges, but may potentially decrease die size efficiency, and may complicate electrically connecting appropriate components and circuitry. For example, the input/output (I/O) connections on memory cell control circuitry may be formed in the uppermost layers of the memory cell control circuitry and consume a large amount of area. Sense Amplifiers, DLMUXs, and SWDs, which have larger component size requirements than memory cells, but which are first connected to memory cells, may be formed in the lower levels, e.g., layers, of memory cell control circuitry.

In a F2F memory array to memory cell control circuitry connection tolerances for mechanical and electrical bonding may be improved and semiconductor fabrication process sequencing/flow relative to wafer to wafer overlay constraints may be eased. However, one disadvantageous result result may be in the upper level, I/O connections now facing an uppermost level of the memory array and this can result in difficulty connecting memory cells in the memory array in first, or direct, order to the sense amplifiers, DLMUXs, and SWDs to which first connection and access is intended, before I/O connections.

Accordingly, embodiments of the present disclosure provide for a pitch interface layer, including a memory cell control component, electrically connecting the memory array to the memory cell control circuitry in a face (F2F) orientation for improved alignment tolerances, and to ease wafer to wafer overlay constraints, but additionally to ease electrical connections and maintain die size efficiency between the memory array and memory cell control circuitry. In some embodiments, the memory cell control circuitry components of digit line multiplexers (DLMUXs) and sub-wordline drivers (SWDs) are formed in the pitch interface layer, electrically connecting a three-dimensional (3D) dynamic random access memory (DRAM) cell structure on a memory array to the memory cell control circuitry. Thus, a first portion of the memory cell control circuitry components, e.g., memory array logic, remains on the memory cell control circuitry layers, including I/O connections, and a second portion of the memory cell control circuitry component(s) are located in the pitch interface layer and configured to distribute array efficiency (AE), wafer usage density, and reduce overlay constraints, e.g., improve alignment tolerances. In some embodiments, the memory cell control circuitry components of sense amplifiers (SAs) and SWDs for the 3D DRAM array are formed in a pitch interface layer, electrically connecting the 3D DRAM array to the memory cell control circuitry with the same connection and fabrication goals stated herein. Embodiments, however, are not limited to the above examples of which memory cell control circuitry components are relocated from the memory cell control circuitry layers to the pitch interface layer. For example, the memory cell control circuitry layer may have the highest power (e.g., Voltage) consumption/usage components, e.g., in and among layers in system on a chip (SOC) architecture, The pitch interface layer, including a memory cell control component, may comprise intermediate power consumption/usage components formed thereon and the memory array comprising the lowest power consumption/usage of the combination. For example, the 3D DRAM components formed in the memory array may have the lowest power consumption/usage among the wafers in wafer to wafer/system on a chip (SOC) architecture. According to embodiments of the present disclosure, the pitch interface layer, including a memory cell control component, arrangement and system architecture electrically connects the memory cell control circuitry to the memory array using a hybrid copper (Cu) to copper (Cu) and copper to oxide bonding process between the memory cell control circuitry and the memory array, easing semiconductor fabrication process sequencing and flow complexity, but still maintaining relaxed overlay constraints.

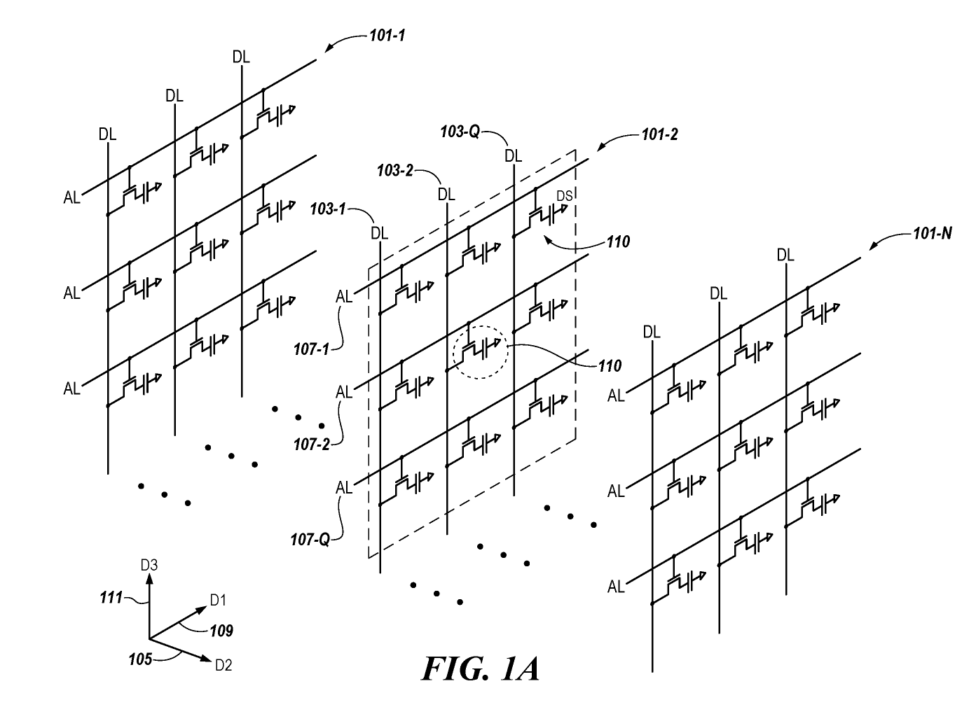

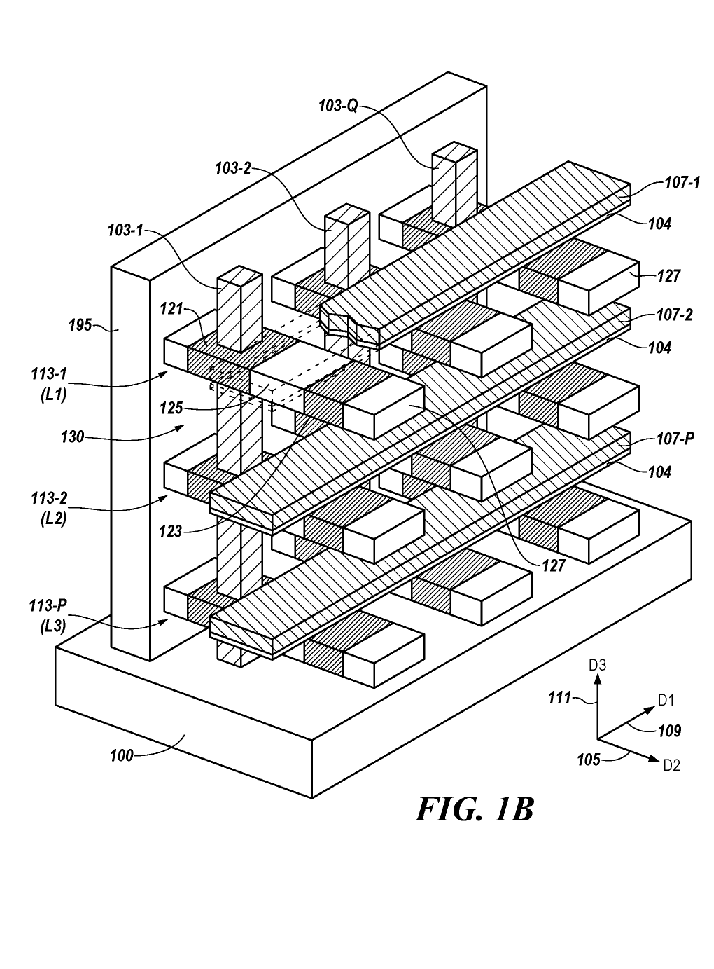

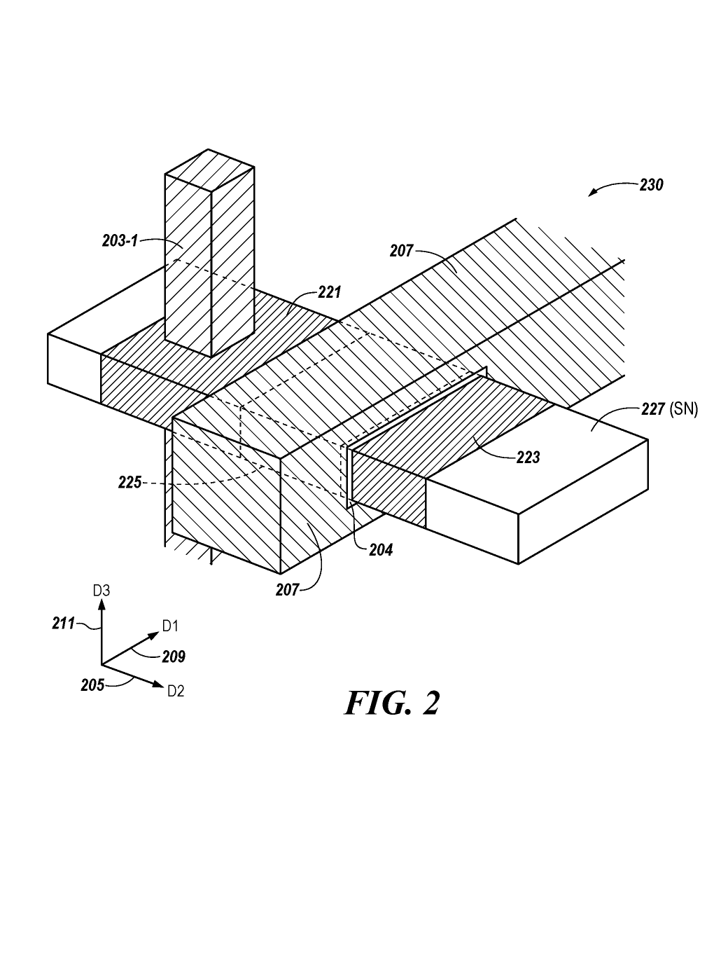

The figures herein follow a numbering convention in which the first digit or digits correspond to the figure number of the drawing and the remaining digits identify an element or component in the drawing. Similar elements or components between different figures may be identified by the use of similar digits. For example, reference numeral 103 may reference element “03” in FIG. 1A, and a similar element may be referenced as 203 in FIG. 2. Multiple analogous elements within one figure may be referenced with a reference numeral followed by a hyphen and another numeral or a letter. For example, 107-1 may reference element 107-1 in FIG. 1A and 107-2 may reference element 107-2, which may be analogous to element 107-1. Such analogous elements may be generally referenced without the hyphen and extra numeral or letter. For example, elements 107-1 and 107-2 or other analogous elements may be generally referenced as 107.

FIG. 1A is a schematic illustration of an array of memory cells in a vertical three dimensional (3D) memory in accordance with a number of embodiments of the present disclosure. FIG. 1A illustrates that a cell array may have a plurality of sub cell arrays 101-1, 101-2, . . ., 101-N. The sub cell arrays 101-1, 101-2, . . ., 101-N may be arranged along a second direction (D2) 105. Each of the sub cell arrays, e.g., sub cell array 101-2, may include a plurality of access lines 107-1, 107-2, . . ., 107-Q (which also may be referred to a word lines). Also, each of the sub cell arrays, e.g., sub cell array 101-2, may include a plurality of digit lines 103-1, 103-2, . . ., 103-Q (which also may be referred to as bit lines, data lines, or sense lines). In FIG. 1A, the access lines 107-1, 107-2, . . ., 107-Q are illustrated extending in a first direction (D1) 109 and the digit lines 103-1, 103-2, . . ., 103-Q are illustrated extending in a third direction (D3) 111. According to embodiments, the first direction (D1) 109 and the second direction (D2) 105 may be considered in a horizontal (“X-Y”) plane. The third direction (D3) 111 may be considered in a vertical (“Z”) plane. Hence, according to embodiments described herein, the digit lines 103-1, 103-2, . . ., 103-Q are extending in a vertical direction, e.g., third direction (D3) 111.

A memory cell, e.g., 110, may include an access device, e.g., access transistor, and a storage node located at an intersection of each access line 107-1, 107-2, . . ., 107-Q and each digit line 103-1, 103-2, . . ., 103-Q. Memory cells may be written to, or read from, using the access lines 107-1, 107-2, . . ., 107-Q and digit lines 103-1, 103-2, . . ., 103-Q. The access lines 107-1, 107-2, . . ., 107-Q may conductively interconnect memory cells along horizontal rows of each sub cell array 101-, 101-2, . . ., 101-N, and the digit lines 103-1, 103-2, . . ., 103-Q may conductively interconnect memory cells along vertical columns of each sub cell array 101-1, 101-2, . . ., 101-N. One memory cell, e.g., 110, may be located between one access line, e.g., 107-2, and one digit line, e.g., 103-2. Each memory cell may be uniquely addressed through a combination of an access line 107-1, 107-2, . . ., 107-Q and a digit line 103-1, 103-2, . . ., 103-Q.

The access lines 107-1, 107-2, . . ., 107-P may be or include conducting patterns (e.g., metal lines) disposed on and spaced apart from a substrate. The access lines 107-1, 107-2, . . ., 107-Q may extend in a first direction (D1) 109. The access lines 107-1, 107-2, . . ., 107-Q in one sub cell array, e.g., 101-2, may be spaced apart from each other in a vertical direction, e.g., in a third direction (D3) 111.

The digit lines 103-1, 103-2, . . ., 103-Q may be or include conductive patterns (e.g., metal lines) extending in a vertical direction with respect to the substrate, e.g., in a third direction (D3) 111. The digit lines in one sub cell array, e.g., 101-2, may be spaced apart from each other in the first direction (D1) 109.

According to embodiments, a gate of a memory cell, e.g., memory cell 110, may be formed by an access line, e.g., 107-2, and a first conductive node, e.g., a first source/drain region, of an access device, e.g., transistor, of the memory cell 110 may be connected to a digit line, e.g., 103-2. Each of the memory cells, e.g., memory cell 110, may be connected to a storage node, e.g., capacitor. A second conductive node, e.g., second source/drain region, of the access device, e.g., transistor, of the memory cell 110 may be connected to the storage node, e.g., capacitor. While first and second source/drain region references are used herein to denote two separate and distinct source/drain regions, it is not intended that the source/drain region referred to as the “first” and/or “second” source/drain regions have some unique meaning. It is intended only that one of the source/drain regions is connected to a digit line, e.g., 103-2, and the other may be connected to a storage node.

FIG. 1B illustrates a perspective view showing a three dimensional (3D) semiconductor memory device, e.g., a portion of a sub cell array 101-2 shown in FIG. 1A as a vertically oriented stack of memory cells in an array, according to some embodiments of the present disclosure.

As shown in FIG. 1B, a substrate 100 may have formed thereon one of the plurality of sub cell arrays, e.g., 101-2, described in connection with FIG. 1A. For example, the substrate 100 may be or include a silicon substrate, a germanium substrate, or a silicon-germanium substrate, etc. Embodiments, however, are not limited to these examples.

As shown in the example embodiment of FIG. 1B, the substrate 100 may have fabricated thereon a vertically oriented stack of memory cells, e.g., memory cell 110 in FIG. 1A, extending in a vertical direction, e.g., third direction (D3) 111. According to some embodiments the vertically oriented stack of memory cells may be fabricated such that each memory cell, e.g., memory cell 110 in FIG. 1A, is formed on plurality of vertical levels, e.g., a first level (L1), a second level (L2), and a third level (L3), etc. The repeating, vertical levels, L1, L2, and L3, may be arranged, e.g., “stacked”, a vertical direction, e.g., third direction (D3) 111 shown in FIG. 1A, and may be separated from the substrate 100 by an insulator material. Each of the repeating, vertical levels, L1, L2, and L3 may include a plurality of discrete components, e.g., regions, to the horizontally oriented access devices 130, e.g., transistors, and storage nodes, e.g., capacitors, including access line 107-1, 107-2, . . ., 107-Q connections and digit line 103-1, 103-2, . . ., 103-Q connections. The plurality of discrete components to the horizontally oriented access devices 130, e.g., transistors, may be formed in a plurality of iterations of vertically, repeating layers within each level and may extend horizontally in the second direction (D2) 105, analogous to second direction (D2) 105 shown in FIG. 1A.

The plurality of discrete components to the laterally oriented access devices 130, e.g., transistors, may include a first source/drain region 121 and a second source/drain region 123 separated by a channel region 125, extending laterally in the second direction (D2) 105, and formed in a body of the access devices. In some embodiments, the channel region 125 may include silicon, germanium, silicon-germanium, and/or indium gallium zinc oxide (IGZO). In some embodiments, the first and the second source/drain regions, 121 and 123, can include an n-type dopant region formed in a p-type doped body to the access device to form an n-type conductivity transistor. In some embodiments, the first and the second source/drain regions, 121 and 123, may include a p-type dopant formed within an n-type doped body to the access device to form a p-type conductivity transistor. By way of example, and not by way of limitation, the n-type dopant may include phosphorous (P) atoms and the p-type dopant may include atoms of boron (B) formed in an oppositely doped body region of polysilicon semiconductor material. Embodiments, however, are not limited to these examples.

The storage node 127, e.g., capacitor, may be connected to one respective end of the access device. As shown in FIG. 1B, the storage node 127, e.g., capacitor, may be connected to the second source/drain region 123 of the access device. The storage node may be or include memory elements capable of storing data. Each of the storage nodes may be a memory element using one of a capacitor, a magnetic tunnel junction pattern, and/or a variable resistance body which includes a phase change material, etc. Embodiments, however, are not limited to these examples. In some embodiments, the storage node associated with each access device of a unit cell, e.g., memory cell 110 in FIG. 1A, may similarly extend in the second direction (D2) 105, analogous to second direction (D2) 105 shown in FIG. 1A.

As shown in FIG. 1B a plurality of horizontally oriented access lines 107-1, 107-2, . . ., 107-Q extend in the first direction (D1) 109, analogous to the first direction (D1) 109 in FIG. 1A. The plurality of horizontally oriented access lines 107-1, 107-2, . . ., 107-Q may be analogous to the access lines 107-1, 107-2, . . ., 107-Q shown in FIG. 1A. The plurality of horizontally oriented access lines 107-1, 107-2, . . ., 107-Q may be arranged, e.g., “stacked”, along the third direction (D3) 111. The plurality of horizontally oriented access lines 107-1, 107-2, . . ., 107-Q may include a conductive material. For example, the conductive material may include one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc. Embodiments, however, are not limited to these examples.

Among each of the vertical levels, (L1) 113-1, (L2) 113-2, and (L3) 113-P, the horizontally oriented memory cells, e.g., memory cell 110 in FIG. 1A, may be spaced apart from one another horizontally in the first direction (D1) 109. However, the plurality of discrete components to the horizontally oriented access devices 130, e.g., first source/drain region 121 and second source/drain region 123 separated by a channel region 125, extending laterally in the second direction (D2) 105, and the plurality of horizontally oriented access lines 107-1, 107-2, . . ., 107-Q extending laterally in the first direction (D1) 109, may be formed within different vertical layers within each level. For example, the plurality of horizontally oriented access lines 107-1, 107-2, . . ., 107-Q, extending in the first direction (D1) 109, may be formed on a top surface opposing and electrically electrically connected to the channel regions 125, separated therefrom by a gate dielectric, and orthogonal to horizontally oriented access devices 130, e.g., transistors, extending in laterally in the second direction (D2) 105. In some embodiments, the plurality of horizontally oriented access lines 107-1, 107-2, . . ., 107-Q, extending in the first direction (D1) 109 are formed in a higher vertical layer, farther from the substrate 100, within a level, e.g., within level (L1), than a layer in which the discrete components, e.g., first source/drain region 121 and second source/drain region 123 separated by a channel region 125, of the horizontally oriented access device are formed.

As shown in the example embodiment of FIG. 1B, the digit lines, 103-1, 103-2, . . ., 103-Q, extend in a vertical direction with respect to the substrate 100, e.g., in a third direction (D3) 111. Further, as shown in FIG. 1B, the digit lines, 103-1, 103-2, . . ., 103-Q, in one sub cell array, e.g., sub cell array 101-2 in FIG. 1A, may be spaced apart from each other in the first direction (D1) 109. The digit lines, 103-1, 103-2, . . ., 103-Q, may be provided, extending vertically relative to the substrate 100 in the third direction (D3) 111 in vertical alignment with source/drain regions to serve as first source/drain regions 121 or, as shown, be vertically adjacent first source/drain regions 121 for each of the horizontally oriented access devices 130, e.g., transistors, extending laterally in the second direction (D2) 105, but adjacent to each other on a level, e.g., first level (L1), in the first direction (D1) 109. Each of the digit lines, 103-1, 103-2, . . ., 103-Q, may vertically extend, in the third direction (D3), on sidewalls adjacent first source/drain regions 121 of respective ones of the plurality of horizontally oriented access devices 130, e.g., transistors, that are vertically stacked. In some embodiments, the plurality of vertically oriented digit lines 103-1, 103-2, . . ., 103-Q, extending in the third direction (D3) 111, may be connected to side surfaces of the first source/drain regions 121 directly and/or through additional contacts including metal silicides.

For example, a first one of the vertically extending digit lines, e.g., 103-1, may be adjacent a sidewall of a first source/drain region 121 to a first one of the horizontally oriented access devices 130, e.g., transistors, in the first level (L1) 113-1, a sidewall of a first source/drain region 121 of a first one of the horizontally oriented access devices 130, e.g., transistors, in the second level (L2) 113-2, and a sidewall of a first source/drain region 121 a first one of the horizontally oriented access devices 130, e.g., transistors, in the third level (L3) 113-P, etc. Similarly, a second one of the vertically extending digit lines, e.g., 103-2, may be adjacent a sidewall to a first source/drain region 121 of a second one of the horizontally oriented access devices 130, e.g., transistors, in the first level (L1) 113-1, spaced apart from the first one of horizontally oriented access devices 130, e.g., transistors, in the first level (L1) 113-1 in the first direction (D1) 109. And the second one of the vertically extending digit lines, e.g., 103-2, may be adjacent a sidewall of a first source/drain region 121 of a second one of the laterally oriented access devices 130, e.g., transistors, in the second level (L2) 113-2, and a sidewall of a first source/drain region 121 of a second one of the horizontally oriented access devices 130, e.g., transistors, in the third level (L3) 113-P, etc. Embodiments are not limited to a particular number of levels.

The vertically extending digit lines, 103-1, 103-2, . . ., 103-Q, may include a conductive material, such as, for example, one of a doped semiconductor material, a conductive metal nitride, metal, and/or a metal-semiconductor compound. The digit lines, 103-1, 103-2, . . ., 103-Q, may correspond to digit lines (DL) described in connection with FIG. 1A.

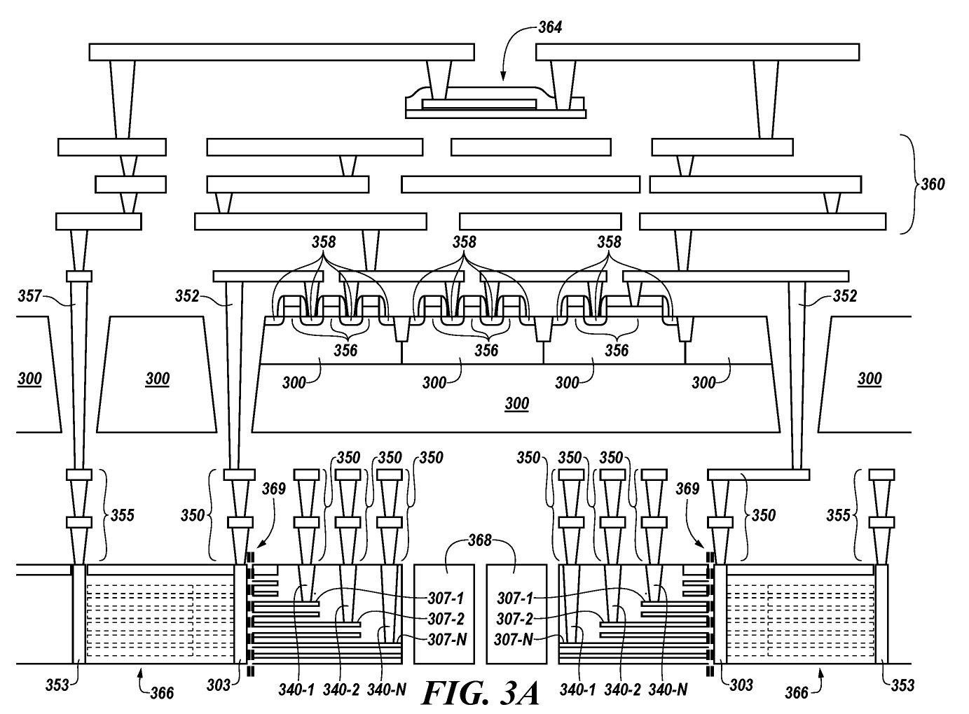

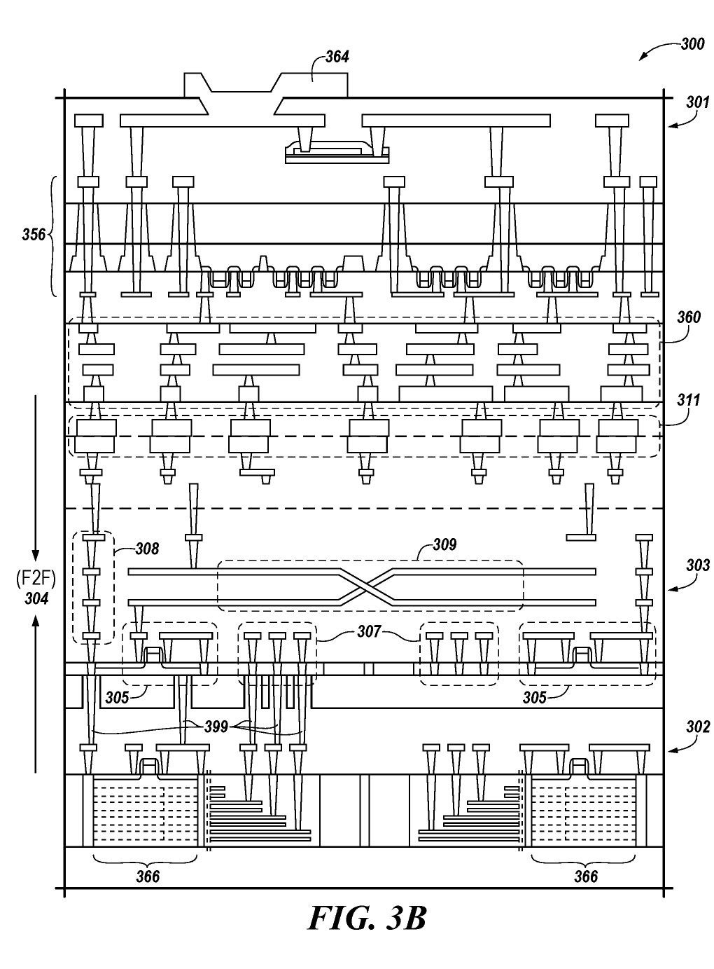

As shown in the example embodiment of FIG. 1B, a conductive body contact may be formed extending in the first direction (D1) 109 along an end surface of the horizontally oriented access devices 130, e.g., transistors, in each level (L1) 113-1, (L2) 113-2, and (L3) 113-P above the substrate 100. The body contact 196 may be connected to a body (as shown by 336 in FIG. 3) e.g., body region, of the horizontally oriented access devices 130, e.g., transistors, in each memory cell, e.g., memory cell 110 in FIG. 1A. The body contact may include a conductive material such as, for example, one of a doped semiconductor material, a conductive metal nitride, metal, and/or a metal-semiconductor compound.

Although not shown in FIG. 1B, an insulating material may fill other spaces in the vertically stacked array of memory cells. For example, the insulating material may include one or more of a silicon oxide material, a silicon nitride material, and/or a silicon oxynitride material, etc. Embodiments, however, are not limited to these examples.

FIG. 2 illustrates a portion of a horizontal access device in vertical three-dimensional (3D) memory in accordance with a number of embodiments of the present disclosure. FIG. 2 illustrates in more detail a unit cell, e.g., memory cell 110 in FIG. 1, of the vertically stacked array of memory cells, e.g., within a sub cell array 101-2 in FIG. 1, according to some embodiments of the present disclosure. As shown in FIG. 2, the first and the second source/drain regions, 221 and 223, may be impurity doped regions to the laterally oriented access devices 230, e.g., transistors. The first and the second source/drain regions may be separated by a channel 225 formed in a body of semiconductor material, e.g., body region of the horizontally oriented access devices 230, e.g., transistors. The first and the second source/drain regions, 221 and 223, may be formed from an n-type or p-type dopant doped in the body region. However, embodiments are not so limited.

For example, for an n-type conductivity transistor construction the body region of the laterally oriented access devices 230, e.g., transistors, may be formed of a low doped p-type (p-) semiconductor material. In one embodiment, the body region and the channel 225 separating the first and the second source/drain regions, 221 and 223, may include a low doped, p-type (e.g., low dopant concentration (p-)) polysilicon (Si) material consisting of boron (B) atoms as an impurity dopant to the polycrystalline silicon. The first and the second source/drain regions, 221 and 223, may also comprise a metal, and/or metal composite materials containing ruthenium (Ru), molybdenum (Mo), nickel (Ni), titanium (Ti), copper (Cu), a highly doped degenerate semiconductor material, and/or at least one of indium oxide (In2O3), or indium tin oxide (In2-xSnxO3), formed using an atomic layer deposition process, etc. Embodiments, however, are not limited to these examples. As used herein, a degenerate semiconductor material is intended to mean a semiconductor material, such as polysilicon, containing a high level of doping with significant interaction between dopants, e.g., phosphorus (P), boron (B), etc. Non-degenerate semiconductors, by contrast, contain moderate levels of doping, where the dopant atoms are well separated from each other in the semiconductor host lattice with negligible interaction.

In this example, the first and the second source/drain regions, 221 and 223, may include a high dopant concentration, n-type conductivity impurity (e.g., high dopant (n+)) doped in the first and the second source/drain regions, 221 and 223. In some embodiments, the high dopant, n-type conductivity first and second drain regions 221 and 223 may include a high concentration of phosphorus (P) atoms deposited therein. Embodiments, however, are not limited to this example. In other embodiments, the horizontally oriented access devices 230, e.g., transistors, may be of a p-type conductivity construction in which case the impurity, e.g., dopant, conductivity types would be reversed.

As shown in FIG. 2, the first and the second source/drain regions, 221 and 223, may be impurity doped regions to the laterally oriented access devices 230, e.g., transistors. The first and the second source/drain regions may be separated by a channel 225 formed in a body of semiconductor material, e.g., body region, of the horizontally oriented access devices 230, e.g., transistors. The first and the second source/drain regions, 221 and 223, may be formed from an n-type or p-type dopant doped in the body region. However, embodiments are not so limited.

The first source/drain region 221 may occupy an upper portion in the body of the laterally oriented access devices 230, e.g., transistors. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented transistor 230 may have a body portion which is below the first source/drain region 221 and is in electrical contact with the body contact. Further, as shown in the example embodiment of FIG. 2, an access line, e.g., 207, analogous to the access lines 107-1, 107-2, . . ., 107-Q shown in FIG. 1, may disposed on a top surface opposing and electrically connected to a channel region 225, separated therefrom by a gate dielectric 204. The gate dielectric material 204 may include, for example, a high-k dielectric material, a silicon oxide material, a silicon nitride material, a silicon oxynitride material, etc., or a combination thereof. Embodiments are not so limited. For example, in high-k dielectric material examples the gate dielectric material 304 may include one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobite, etc.

As shown in the example embodiment of FIG. 2, a digit line, e.g., 203-1, analogous to the digit lines 103-1, 103-2, . . ., 103-Q in FIG. 1, may be vertically extending in the third direction (D3) 211 adjacent a sidewall of the first source/drain region 221 in the body to the horizontally oriented access devices 230, e.g., transistors horizontally conducting between the first and the second source/drain regions 221 and 223 along the second direction (D2) 205. In this embodiment, the vertically oriented digit line 203-1 is formed symmetrically, in vertical alignment, in electrical contact with the first source/drain region 221. The digit line 203-1 may be formed in contact with an insulator material such that there is no body contact within channel 225.

As shown in the example embodiment of FIG. 2, the digit line 203-1 may be formed symmetrically within the first source/drain region 221 such that the first source/drain region 221 surrounds the digit line 203-1 all around. The first source/drain region 221 may occupy an upper portion in the body of the laterally oriented access devices 230, e.g., transistors. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented transistor 230 may have a body portion which is below the first source/drain region 321 and is in contact with the body contact. An insulator material may fill the body contact such that the first source/drain region 221 may not be in electrical contact with channel 225. Further, as shown in the example embodiment of FIG. 2, an access line, e.g., 207, analogous to the access lines 107-1, 107-2, . . ., 107-Q shown in FIG. 1, may disposed all around and electrically connected to a channel region 225, separated therefrom by a gate dielectric 204.

Although the digit line 203-1 is described above as being formed symmetrically within the first source/drain region 221 such that the first source/drain region 221 surrounds the digit line 203-1 all around, embodiments are not so limited. For instance, in some examples, the digit line 203-1 can be formed asymmetrically. In this embodiment, the vertically oriented digit line is formed asymmetrically adjacent in electrical contact with the first source/drain regions 221. The digit line may be formed asymmetrically to reserve room for a body contact in the channel region 225.

FIG. 3A is a schematic illustration of a vertical three dimensional (3D) memory in functional association with logic components for the 3D memory array. The logic components may include complementary metal oxide semiconductor (CMOS) components such as input/output (I/O) connections, sense amplifiers (SAs), digit line multiplexers (DLMUXs), sub-wordline drivers (SWDs), etc., in accordance with a number of embodiments of the present disclosure. FIG. 3A includes horizontally oriented access lines 307-1, 307-2, . . ., 307-N (individually or collectively referred to as horizontally access lines 307), access line contacts 340-1, 340-2, . . ., 340-N (individually or collectively referred to as access line contacts 340), and vertically oriented sense lines 303 (e.g., digit lines), connected to a dynamic random access memory (DRAM) cell structure of horizontally oriented, vertically stacked memory cells, having horizontally oriented access devices and horizontally oriented storage nodes.

The schematic illustration in FIG. 3A portrays different components relating to the function, operation, and control of the vertical 3D memory at different vertical heights on the page of the drawing sheet. In the portion of the vertical 3D memory at the lowest vertical height shown in FIG. 3A is illustrated a dynamic random access memory array (DRAM) of horizontally oriented, vertically stacked memory cells in a plurality of levels. The outermost edges of the bottom of the drawing sheet illustrate the 3D DRAM in an “x”-direction, cross-sectional view along a “length” of horizontally oriented access devices connected to horizontally oriented storage nodes. In the center region of the bottom of the drawing sheet, partitioned by a cut line, is illustrated an example embodiment of a staircase structure in a periphery of the vertical 3D memory, along a y-direction, cross sectional view (end on to the memory cells) that includes horizontally oriented access lines 307-which would be running into and out of the plane of the drawing sheet in the outermost x-direction view of the 3D DRAM memory array. As used herein, the term “periphery of the vertical 3D memory” refers to an area located outside of the array of memory cells for forming and making electrical contacts to array of memory cells. In some embodiments, periphery components and electrical connections can consume more area and have greater die space usage than that of the array of memory cells itself. Isolation regions 368 may separate neighboring arrays of vertical 3D memory in “x” and/or “y” directions of a memory die having a memory array.

To connect “on pitch” in a socket to socket, e.g., component to component architecture, e.g., memory cell control circuitry to memory array, various electrical connection routing challenges may exist. As used herein, the term “pitch” is intended to refer to a length and/or width dimension of a conductive feature and its minimum separation from a next feature according to a certain design rule or fabrication capability. Thus “on-pitch” as used herein is intended to mean a capability to establish and match electrical features, circuitry, and/or components to one another between different structures and/or layers, e.g., memory cell control circuitry connections to memory array connections. Hence, in the schematic illustration of FIG. 3A, forming electrical connections to circuitry and components of different size and locations elsewhere in the schematic illustration, while accommodating design rules, including power consumption, die density usage, and overlay alignment constraints, present hurdles. Larger than memory cell access device transistor size, the transistor component size for address decode logic, sense amplifiers circuitry, DLMUXs, and SWDs, may all consume more space and be located elsewhere as logic, e.g., CMOS logic, shown above in the schematic of FIG. 3A, but have electrical connection to the 3D DRAM array. For example, in the schematic illustration of FIG. 3A, access line contacts 340 are electrically connected to the access lines 307. In some embodiments, the access line contacts 340 can be electrically connected to additional transistor logic in the form of SWDs 350. In some embodiments, SWDs 350 can be electrically connected to a power source that can supply power to the access lines 307 through the access line contacts 340. The transistor size to the access devices in the memory cell portion 366 of the vertical 3D memory may have a significantly smaller “pitch”, as described elsewhere herein.

As further shown in the schematic illustration of FIG. 3A a portion of the logic controlling the function and operation, e.g., memory cell control circuitry 356, of the vertical 3D memory array 366 can be in logic shown further above in the drawing sheet. This portion of CMOS logic 356, e.g., circuitry, can include address decode circuity, DLMUXs, and/or sense amplifier (SA) transistor logic, etc. Larger and appropriately doped source/drain region 358 sizes (e.g., larger and heavier doping than memory cell access device size and doping concentrations) and may be formed separately on memory cell control circuitry substrate materials 300. Conductive lines and/or logic 352 and 351 can couple CMOS circuitry 356 to digit lines 303 associated with the array 366, as well as to conductive lines 360 for I/O connections. Further, power supply transistor logic 364 may control one or more storage node electrodes 353, e.g., top electrode/common nodes, for the storage nodes in the array portion 366 via conductive lines and/or logic 357 and 355 pathways. Embodiments are not limited to this schematic example shown in FIG. 3A.

As mentioned above, in some approaches memory arrays may be joined to memory cell control circuitrys in a face to back (F2B) manner with complex electrical connections achieved to overcome to electrical connection routing hurdles. In other approaches, memory arrays may be joined to memory cell control circuitry in a face to face (F2F) manner to accommodate wafer die size, convenience of fabrication sequencing/flow, or die usage density issues. According to embodiments of the present disclosure, a pitch interface layer, including a memory cell control component, having a portion of logic components and/or circuitry, e.g., DLMUXs, SWDs, and/or SAs, etc., is used to electrically and mechanically connect a memory array to memory cell control circuitry to improve alignment tolerance 399 and balance die size efficiency, wafer density usage.

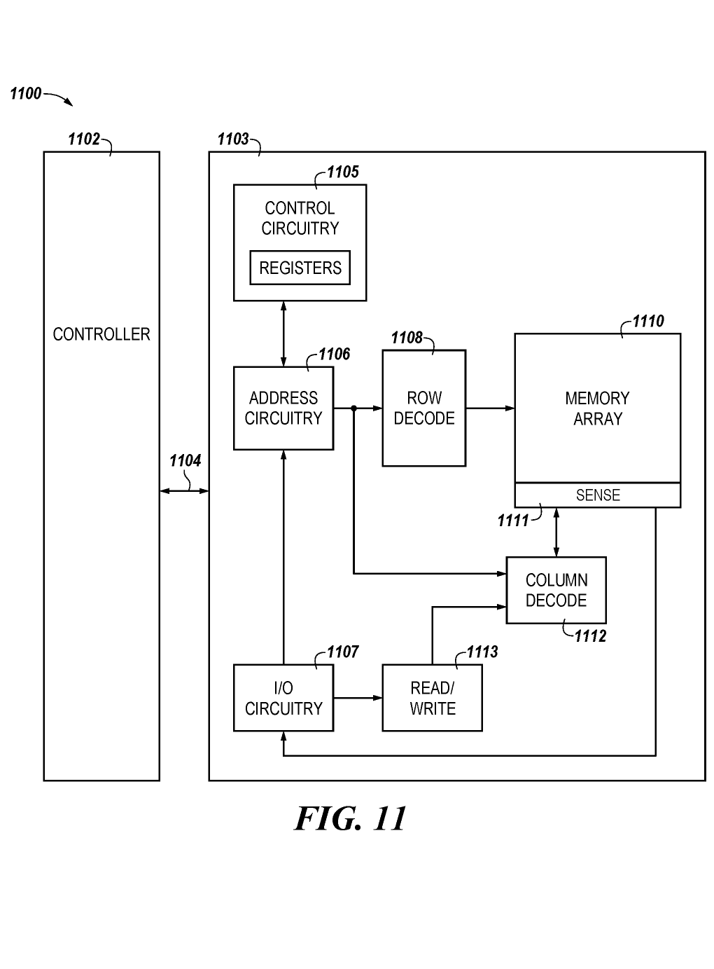

FIG. 3B, illustrates an example embodiment having a pitch interface layer, including a memory cell control component, 303 electrically and mechanically join a memory array 302 to memory cell control circuitry 301. As shown in the example embodiment of FIG. 3B, a device 300, e.g., memory device 1103 in FIG. 11, can include memory cell control circuitry 301 having complementary metal oxide semiconductor (CMOS) logic 356, and a memory array 302 having a three-dimensional (3D) dynamic random access memory (DRAM) cell structure 366. According to embodiments, a pitch interface layer, including a memory cell control component, 303 electrically and mechanically connects the memory cell control circuitry 301 to the memory array 302 in a face to face (F2F) orientation 304.

In some embodiments, the pitch interface layer, including a memory cell control component, 303 has digit line multiplexers (DLMUXs) 305 and sub-wordline drivers (SWDs) 307 for the 3D DRAM array 366 formed thereon. The DLMUXs 305 and SWDs 307 electrically connect 309 the 3D DRAM array 302 to other electrical components, e.g., CMOS logic 356, on the memory cell control circuitry 301. In some embodiments, the pitch interface layer 303, including a memory cell control component, has sense amplifiers (SAs) (not shown in the embodiment of FIG. 3B) and sub-wordline drivers 307 for the 3D DRAM array 366 formed thereon, electrically connecting 309 the 3D DRAM array 302 to other electrical components, e.g., CMOS logic 356, on the memory cell control circuitry 301. According to embodiments, the pitch interface layer 303, including a memory cell control component, electrically connects the memory cell control circuitry 301 to the memory array 320 using a hybrid copper (Cu) to copper (Cu) and copper to oxide bonds 311 with the memory cell control circuitry 310 and the memory array 302.

As shown in FIG. 3B, the memory cell control circuitry 301 is formed to include a first portion of memory cell control circuitry components 356 (having first power consumption usage), including input/output (I/O) connections 360. The pitch interface layer, including a memory cell control component, 303 is formed to include a second portion of memory cell control circuitry components 305/307. The second portion of memory cell control circuitry components 305/307 is configured to distribute array efficiency, wafer usage density, and reduce overlay constraints. The second portion of the memory cell control circuitry components 305/307 may have a second power consumption usage, different from the first power consumption usage of the first portion of memory cell control circuitry components 356 on the memory cell control circuitry 301. In some embodiments, the second power consumption usage on the pitch interface layer, including a memory cell control component, 303 is less than the first power consumption usage on the memory cell control circuitry 301. For example, the memory cell control circuitry 301 may have the highest power (e.g., Voltage (V)) consumption/usage components formed thereon among wafers in a wafer to wafer/system on a chip (SOC) architecture 300. The pitch interface layer, including a memory cell control component, 303 may comprise intermediate power consumption/usage components formed thereon and the memory array 302 may comprise the lowest power consumption/usage of the combination. For example, the 3D DRAM components 366 formed on the memory array 302 may have the lowest power consumption/usage among the wafers in wafer to wafer/system on a chip (SOC) architecture 300.

According to embodiments, the pitch interface layer 303, including a memory cell control component, having a second portion of memory cell control circuitry components 305/307 electrically connects 309 the memory cell control circuitry 301 to the memory array 302 in a face to face (F2F) orientation 304. The second portion of the memory cell control circuitry components 305/307 formed on the pitch interface layer 303 is configured to distribute array efficiency (AE), to increase wafer usage density, and/or to reduce wafer to wafer electrical connection constraints 399 and/or overlay constraints. As mentioned above, in some embodiments the second portion of memory cell control circuitry components 305/307 on the pitch interface layer 303 can include digit line multiplexers (DLMUXs) 305 and sub-wordline drivers 307 electrically connected 399 to the DRAM array 366 on the memory array 302 and electrically connected 308 to the first portion of memory cell control circuitry components 356 on the memory cell control circuitry 301. In some embodiments, the second portion of memory cell control circuitry components 305/307 on the pitch interface layer 303 includes sense amplifiers (SAs) and sub-wordline drivers 307 electrically connected to the DRAM array 366 on the memory array 302 and electrically connected to the first portion of memory cell control circuitry components 356 in the memory cell control circuitry 301.

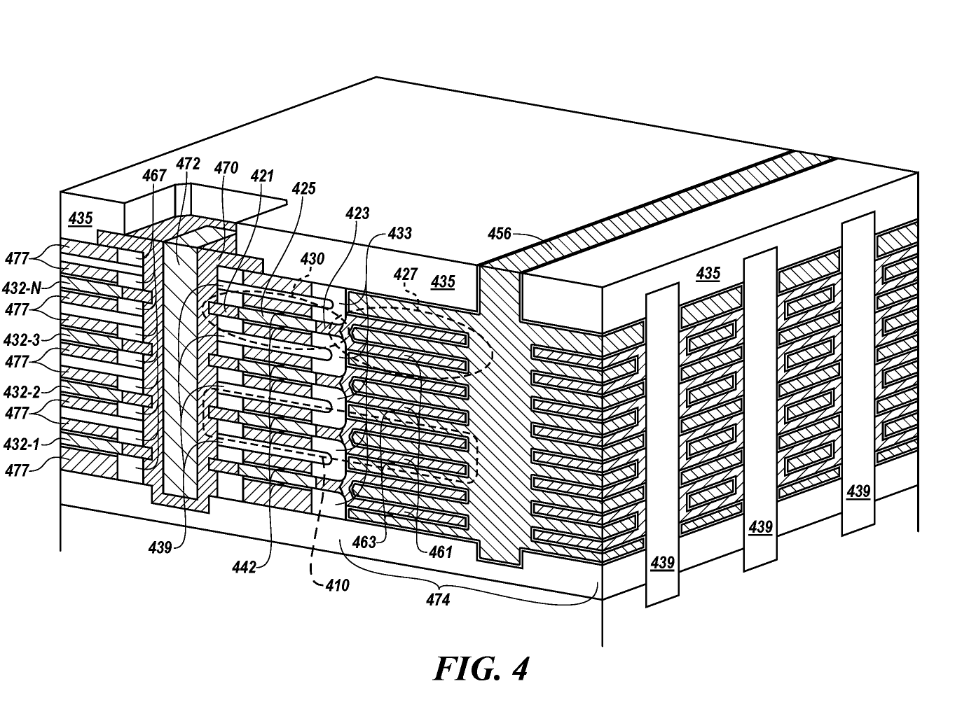

As described below in connection with FIGS. 4, et. Seq., the 3D DRAM array 366 on the memory array 302 has horizontally oriented, vertically stacked memory cells in a plurality of levels. In various embodiments, the array comprises horizontally oriented access devices at each level having first source/drain regions and second source/drain regions separated by channel regions. Horizontally oriented access lines form gates separated from the channel regions by gate dielectric material. Horizontally oriented storage nodes, at each level, are electrically electrically connected to the second source/drain regions of the horizontally oriented access devices. Vertically oriented digit lines electrically connect to the first source/drain regions of the horizontally oriented access devices and to digit line demultiplexers (DLMUXs) 305 in the pitch interface layer, including a memory cell control component, 303.

In some embodiments, as described further in connection with FIGS. 4 et. Seq., the vertically oriented digit lines of the 3D DRAM array 366 on the memory array 302 are epitaxially formed vertical digit lines connected to the first source/drain regions of the horizontally oriented access devices in the array 366. The horizontally oriented access lines of the 3D DRAM array 366 on the memory array 302 form gate all around structures (GAA) separated from the channel regions of the horizontally oriented access devices by gate dielectric material. And, the horizontally oriented storage nodes of the 3D DRAM array 366 on the memory array 302 include multi-sided storage nodes, e.g., double sided capacitors. Embodiments, however, are not so limited to these examples.

FIG. 4 is a perspective view of a three-dimensional (3D) dynamic random access memory (DRAM) cell structure 400 having horizontally oriented memory cells 410, vertically stacked in a plurality of levels, e.g., L1, L2, and L3 in FIG. 1B. The example embodiment of FIG. 4 is illustrating an array of 3D DRAM 400 having horizontally oriented memory cells 410 combinable with pitch interface layers in accordance with a number of embodiments of the present disclosure. The horizontally oriented memory cells 410 in the array 400 comprise horizontally oriented access devices 430 at each level, e.g., L1, L2, and L3 in FIG. 1B, having first source/drain regions 421 and second source/drain regions 423 separated by channel regions 425. Horizontally oriented access lines 477 form gates separated from the channel regions 425 by gate dielectric material 442. As shown in the example embodiment, horizontally oriented storage nodes 474, at each level L1, L2, and L3 in FIG. 1B, are electrically electrically connected to the second source/drain regions 473 of the horizontally oriented access devices 430. The horizontally oriented storage nodes 474 include a first electrode 461, e.g., bottom electrode, and a second electrode 456, e.g., top electrode and/or common node, separated by a dielectric material 461. In some embodiments, the horizontally oriented storage nodes 474 are multi-sided storage nodes, e.g., double sided-capacitors, as shown in FIG. 4. Vertically oriented digit lines 470/472 are electrically connected to the first source/drain regions 421 of the horizontally oriented access devices 430. In some embodiments, a portion 470 of the vertically oriented digit lines are epitaxially formed (e.g., grown), vertically oriented digit lines 470.

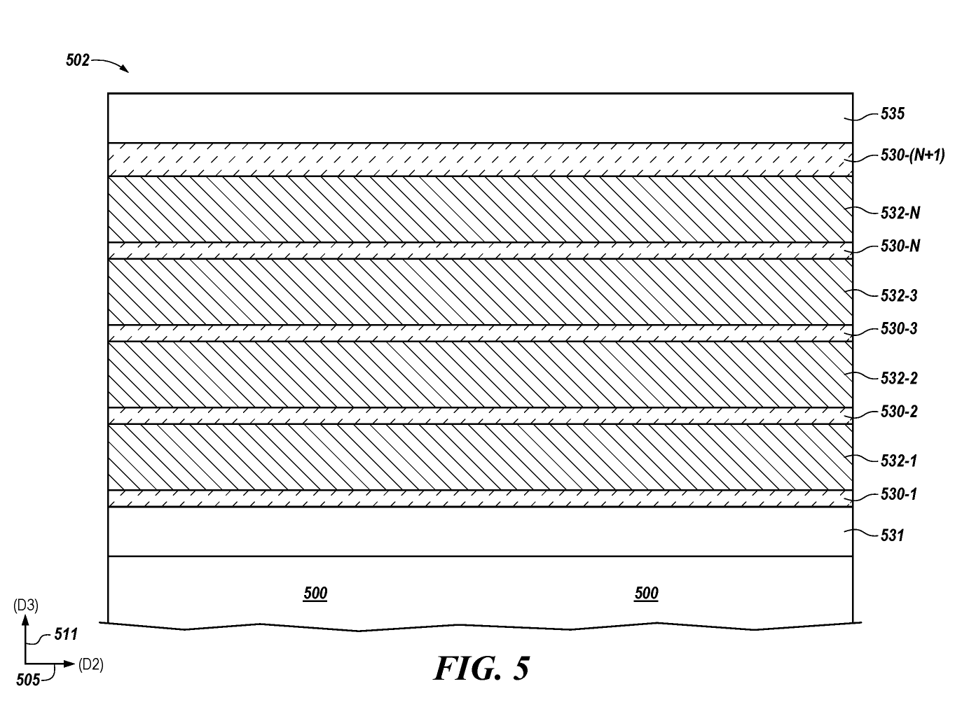

FIG. 5 is a cross-sectional view illustrating an example method, at one stage of a semiconductor fabrication process, for forming vertical three dimensional (3D) memory arrays combinable with pitch interface layers, in accordance with a number of embodiments of the present disclosure. In the example embodiment shown in the example of FIG. 5, a method of forming the vertical stack 501 can comprise forming alternating layers of a silicon germanium (SiGe) material , 530-1, 530-2, . . ., 530-N (collectively referred to as silicon germanium (SiGe) 530), and a silicon (Si) material, 532-1, 532-2, . . ., 532-N (collectively referred to as single crystalline silicon (Si) material 532), in repeating iterations to form a vertical stack 501 on a working surface of a semiconductor substrate 500. In some embodiments, the silicon germanium (SiGe) material and the silicon (Si) material can be epitaxially grown.

In one embodiment, the silicon germanium (SiGe) 530 can be deposited to have a thickness, e.g., vertical height in the third direction (D3), in a range of five (5) nanometers to thirty (30) nm. In one embodiment, the silicon (Si) material 532 can be deposited to have a thickness (t2), e.g., vertical height, in a range of thirty (30) nanometers (nm) to sixty (60) nm. Embodiments, however, are not limited to these examples. As shown in FIG. 5, a vertical direction 511 is illustrated as a third direction (D3), e.g., z-direction in an x-y-z coordinate system, analogous to the third direction (D3), among first, second, and third directions, shown in FIGS. 1-3.

In some embodiments, the silicon germanium (SiGe), 530-1, 530-2, . . ., 530-N, may be a mix of silicon and germanium. By way of example, and not by way of limitation, the silicon germanium (SiGe) material 530 may be grown on the substrate material 500. Embodiments are not limited to these examples. In some embodiments, the single crystalline silicon (Si) material, 532-1, 532-2, . . ., 532-N, may comprise a silicon (Si) material in a polycrystalline and/or amorphous state. The single crystalline silicon (Si) material, 532-1, 532-2, . . ., 532-N, may be a low doped, p-type (p-) single crystalline silicon (Si) material. The silicon (Si) material, 532-1, 532-2, . . ., 532-N, may also be formed on the silicon germanium (SiGe) 530. If the silicon germanium (SiGe) 530 was epitaxially grown, the seed is turned to pure silicon after the silicon germanium (SiGe) 530 has been formed.

The repeating iterations of alternating silicon germanium (SiGe), 530-1, 530-2, . . ., 530-N layers and single crystalline silicon (Si) material, 532-1, 532-2, . . ., 530-N layers may be deposited according to a semiconductor fabrication process such as chemical vapor deposition (CVD) in a semiconductor fabrication apparatus. Embodiments, however, are not limited to this example and other suitable semiconductor fabrication techniques may be used to deposit the alternating layers of silicon germanium (SiGe) and single crystalline silicon (Si) material, in repeating iterations to form the vertical stack 501.

The layers may occur in repeating iterations vertically. For example, the stack may include: a first silicon germanium (SiGe) material 530-1, a first single crystalline silicon (Si) material 532-1, a silicon germanium (SiGe) material 530-2, a second single crystalline silicon (Si) material 532-2, a third silicon germanium (SiGe) material 530-3, and a third single crystalline silicon (Si) material 532-3, in further repeating iterations. Embodiments, however, are not limited to this example and more or fewer repeating iterations may be included.

In some embodiments, a bottom portion of the vertical stack 501 can be removed to form a second horizontal opening. The bottom portion of the vertical stack 501 can include a layer of silicon germanium (SiGe) material 530 that is closer to the substrate 500 than other layers of silicon germanium (SiGe) material 530, a layer of silicon (Si) material 532 that is closer to the substrate 500 than other layers of silicon (Si) material 532, or both. Further, a dielectric material 531 can be deposited to fill the horizontal opening.

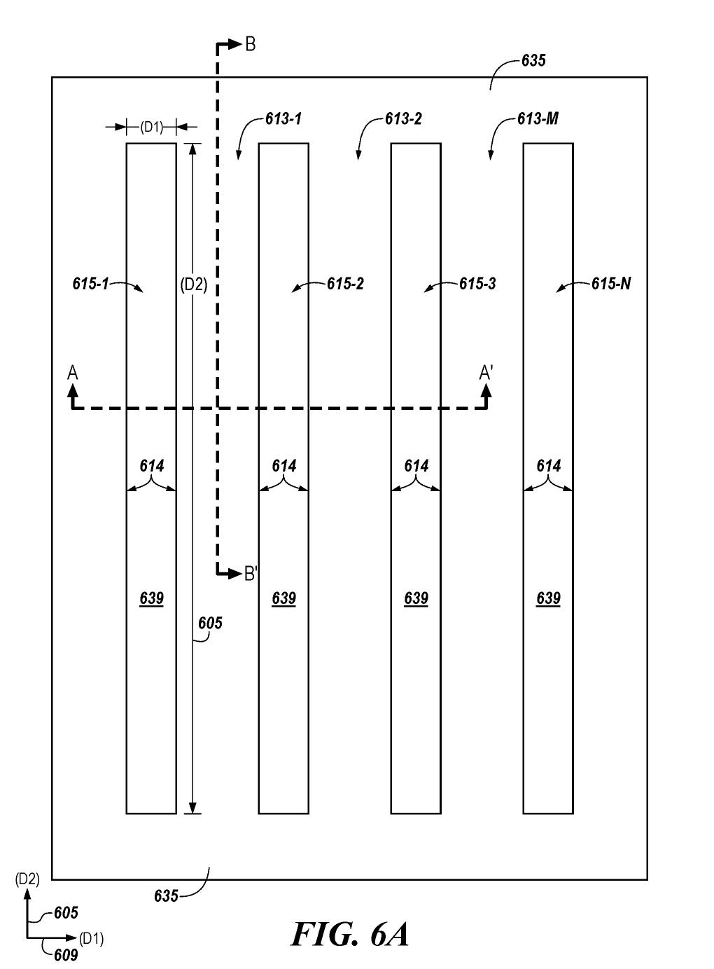

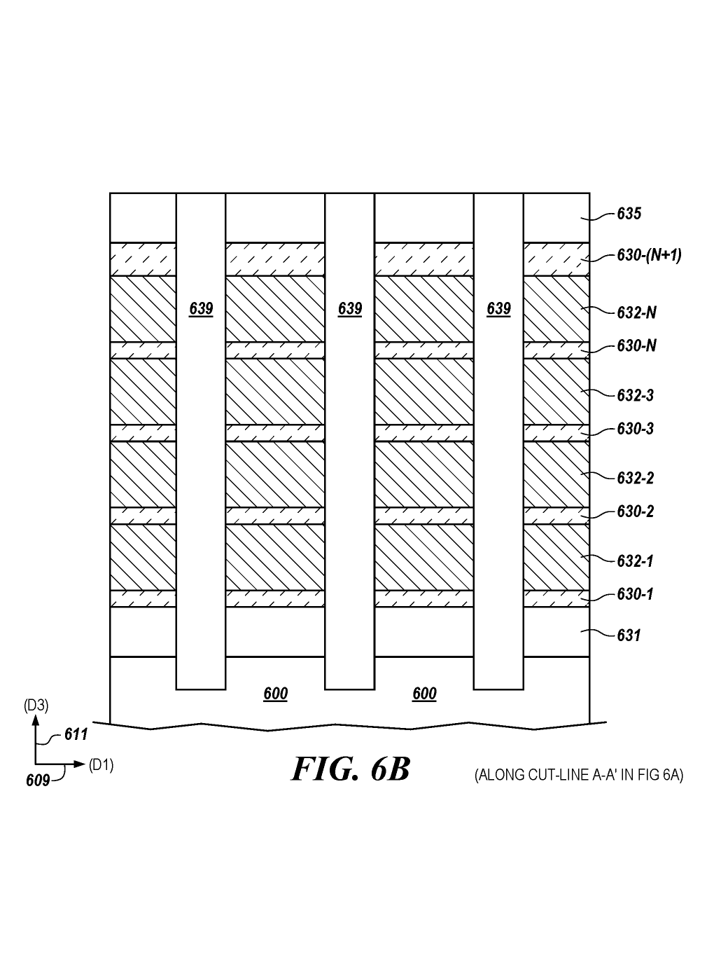

FIG. 6A illustrates an example method, at one stage of a semiconductor fabrication process, for forming vertical three dimensional (3D) memory arrays combinable with pitch interface layers, in accordance with a number of embodiments of the present disclosure. FIG. 6A illustrates a top down view of a semiconductor structure, at a particular point in time, in a semiconductor fabrication process, according to one or more embodiments. In the example embodiment shown in the example of FIG. 6A, the method comprises using an etchant process to form a plurality of vertical openings 615-1, 615-2, 615-3, . . ., 615-N (individually or collectively referred to as vertical openings 615), having a first horizontal direction (D1) 609 and a second horizontal direction (D2) 605, through the vertical stack to the substrate. In one example, as shown in FIG. 6A, the plurality of vertical openings (e.g., fourth vertical openings) 615 are extending predominantly in the second horizontal direction (D2) 605 and may form elongated vertical, pillar columns 613-1, 613-2, . . ., 613-M (collectively and/or independently referred to as vertical, pillar columns 613), with sidewalls 614 in the vertical stack. The plurality of first vertical openings 615 may be formed using photolithographic techniques to pattern a photolithographic mask 635, e.g., to form a hard mask (HM), on the vertical stack prior to etching the plurality of first vertical openings 615. Similar semiconductor process techniques may be used at other points of the semiconductor fabrication process described herein.

The first vertical openings 615 may be filled with a first dielectric material 639. In one example, a spin on dielectric process may be used to fill the first vertical openings 615. In one embodiment, the first dielectric material 639 may be an oxide material. However, embodiments are not so limited.

FIG. 6B is a cross sectional view, taken along cut-line A-A’ in FIG. 6A, showing another view of the semiconductor structure at a particular time in the semiconductor fabrication process for forming vertical three dimensional (3D) memory arrays combinable with pitch interface layers, in accordance with a number of embodiments of the present disclosure. The cross sectional view shown in FIG. 6B shows the repeating iterations of alternating layers of a silicon germanium (SiGe) material 630 and a single crystalline silicon (Si) material 632 on a semiconductor substrate 600 to form the vertical stack, e.g., vertical stack 501 in FIG. 5.

As shown in FIG. 6B, a plurality of vertical openings may be formed through the layers within the vertically stacked memory cells to expose vertical sidewalls in the vertical stack and form elongated vertical pillar columns 613 and then filled with a first dielectric material 639. The first vertical openings 615 may be formed through the repeating iterations of the silicon germanium (SiGe) material 630 and the single crystalline silicon (Si) material 632. As such, the first vertical openings 615 may be formed through a first silicon germanium (SiGe) material 630-1, a first single crystalline silicon (Si) material 632-1, a second silicon germanium (SiGe) material 630-2, a second single crystalline silicon (Si) material 632-2, a third silicon germanium (SiGe) material 630-3, and a third single crystalline silicon (Si) material 632-3. Embodiments, however, are not limited to the vertical opening(s) shown in FIG. 6B. Multiple vertical openings may be formed through the layers of materials. The vertical openings may be formed to expose vertical sidewalls in the vertical stack. The vertical openings may extend in a second direction (D2) 605 to form elongated vertical, pillar columns with vertical sidewalls in the vertical stack and then filled with first dielectric 639.

As shown in FIG. 6B, a first dielectric material 639, such as an oxide or other suitable spin on dielectric (SOD), may be deposited in the first vertical openings 615, using a process such as CVD, to fill the first vertical openings 615. First dielectric material 639 may also be formed from a silicon nitride (Si₃N₄) material. In another example, the first dielectric material 639 may include silicon oxy-nitride (SiOₓN_{y}), and/or combinations thereof. Embodiments are not limited to these examples. The plurality of first vertical openings 615 may be formed using photolithographic techniques to pattern a photolithographic mask 635, e.g., to form a hard mask (HM), on the vertical stack prior to etching the plurality of first vertical openings 615. In one embodiment, hard mask 635 may be deposited over a silicon germanium (SiGe) material 630. Similar semiconductor process techniques may be used at other points of the semiconductor fabrication process described herein.

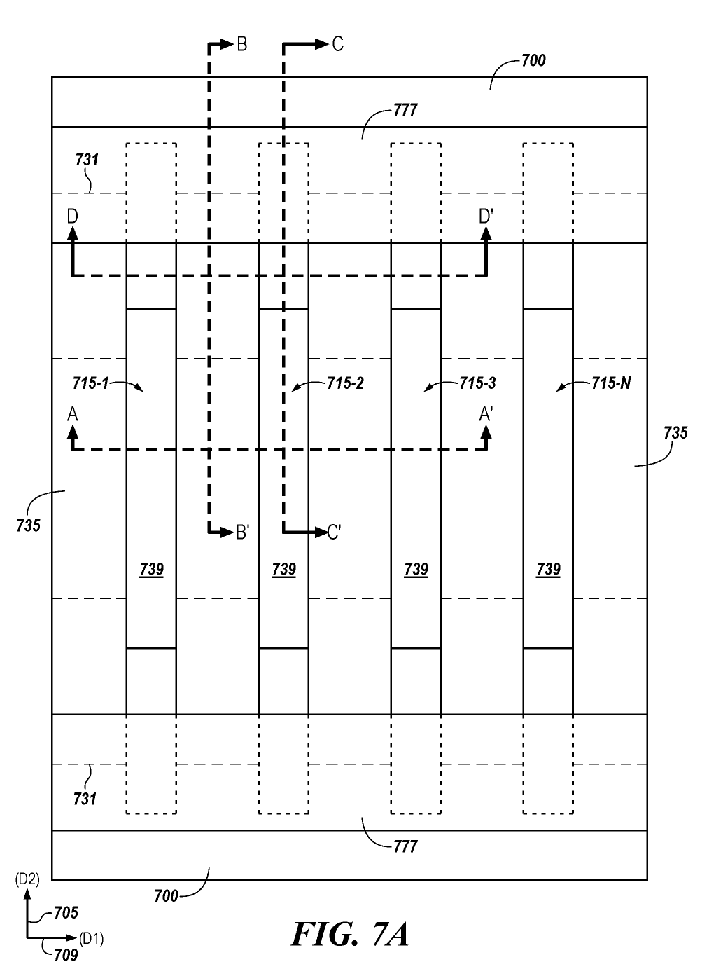

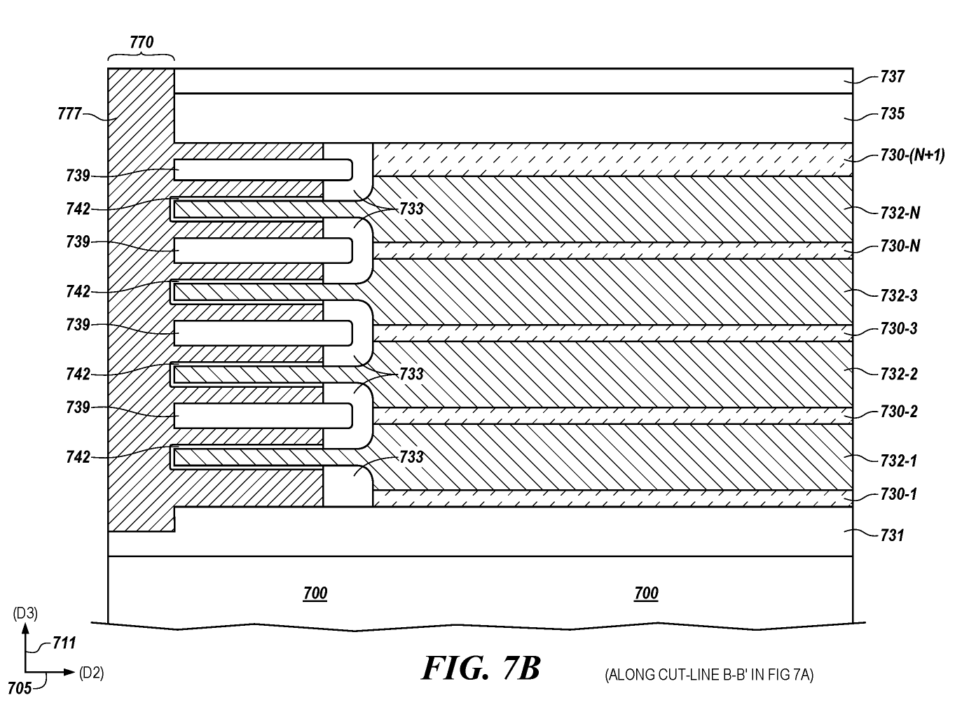

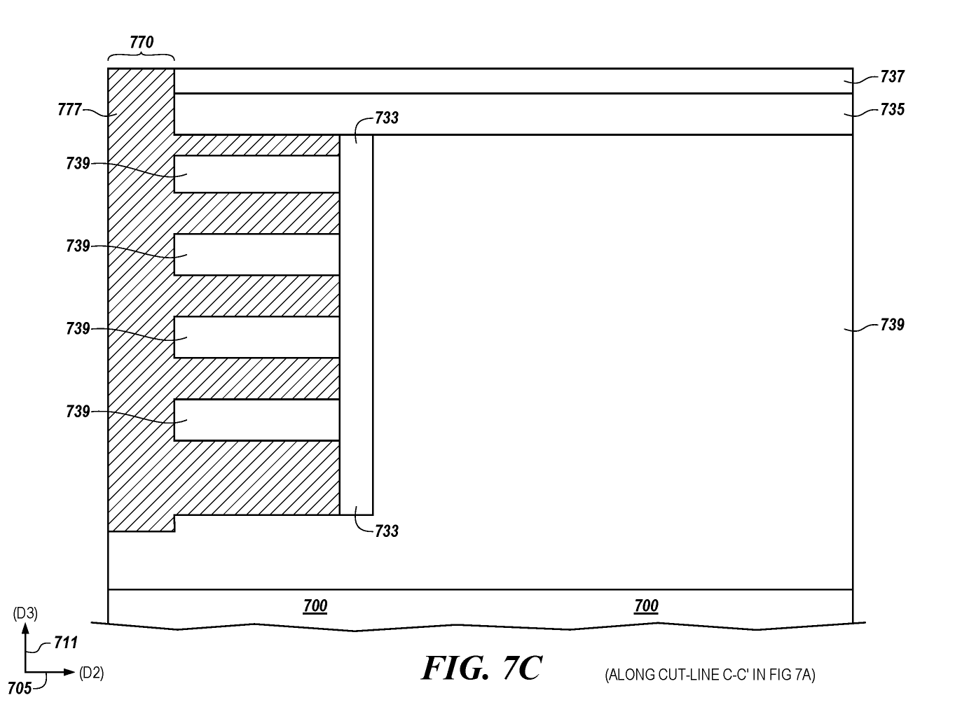

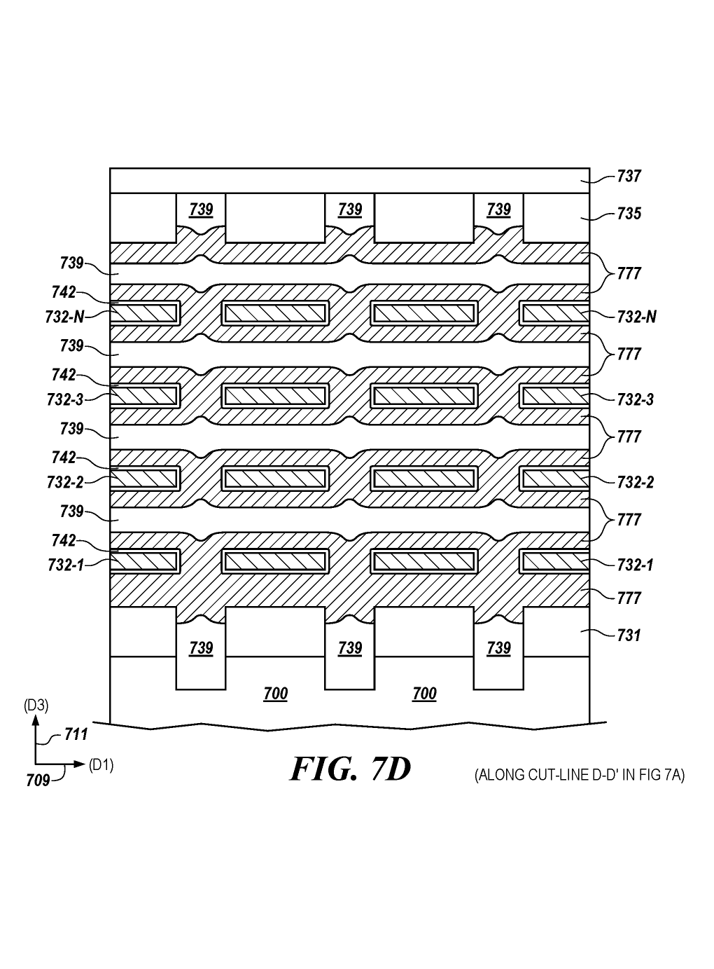

FIG. 7A illustrates an example method, at another stage of a semiconductor fabrication process for forming vertical three dimensional (3D) memory arrays combinable with pitch interface layers, in accordance with a number of embodiments of the present disclosure. FIG. 7A illustrates a top down view of a semiconductor structure, at a particular point in time, in a semiconductor fabrication process, according to one or more embodiments. In the example embodiment of FIG. 7A, the method comprises using a photolithographic process to pattern the photolithographic mask 735 and form second vertical openings 731 extending primarily in the second direction (D2) 705 in an access device region of the structure.

FIG. 7B illustrates a cross sectional view, taken along cut-line B-B’ in FIG. 7A, showing another view of the semiconductor structure at this particular point in one example semiconductor fabrication process for forming vertical three dimensional (3D) memory arrays combinable with pitch interface layers in accordance with embodiments of the present disclosure. The cross-sectional view shown in FIG. 7B is illustrated extending in the second horizontal direction (D2) 705, left and right along the plane of the drawing sheet, along an axis of the repeating iterations of alternating layers of the silicon germanium (SiGe) material 730 and the single crystalline silicon (Si) material 732.

A process of depositing and etching materials is used to form the structure shown in FIG. 7B. In some embodiments, the process of depositing and etching materials can include forming horizontally oriented access devices and horizontally oriented storage nodes (e.g., storage nodes 227 in FIG. 2) at each level of the vertical stack (e.g., vertical stack 501 in FIG. 5) to form an array of vertically stacked memory cells. Each of the horizontally oriented access devices can have first source/drain regions and second source/drain regions separated by channel regions. In some embodiments, gates can be formed fully around every surface of the channel regions as gate all around (GAA) structures on a gate dielectric material. Further, in some embodiments, the second source/drain regions can be electrically connected to storage nodes.

The semiconductor structure shown in FIG. 7B shows the semiconductor structure after the silicon germanium (SiGe) layers are selectively etched to form a plurality of first horizontal openings a first length (dist1) from second vertical openings 770. In some embodiments, the second vertical openings 770 can be formed to a depth in a range of 0.5 to one (1) micrometer (µm). Further, in some embodiments, each of the first vertical openings 770 can be formed to have an aspect ratio in a range of 15-20. In some embodiments, the plurality of first horizontal openings can have a first length (dist1) from the second vertical openings in a range of 150 to 300 nanometers (nm). In some embodiments, the selective etch that forms the plurality of first horizontal openings can also reduce a vertical thickness (Vt) of the silicon (Si) layers 732 in the access device regions of the structure. In some embodiments, a vertical thickness (Vt) of a portion of each of the silicon (Si) layers 732 can be reduced to a vertical thickness in a range of 100-150 Angstroms (Å).

The process of forming the horizontally oriented access devices can further include conformally depositing a second dielectric material 733 on exposed surfaces in the plurality of first horizontal openings and depositing the first dielectric material 739 to fill the plurality of first horizontal openings. The second dielectric material 733 can be selectively etched from the plurality of first horizontal openings a second length (dist2) from the first vertical opening 770. In some embodiments, the second length (dist2) can be a length in a range of 130-170 nanometers (nm).

A first conductive material 777 may be deposited in the plurality of first horizontal openings on a gate dielectric material 742 after selectively etching the second dielectric material 739. The first conductive material 777 may be deposited around the single crystalline silicon (Si) material 732 such that the first conductive material 777 may have a top portion above the single crystalline silicon (Si) material 732 and a bottom portion below the single crystalline silicon (Si) material to form a gate all around (GAA) gate structure, at a channel of an access device region. The first conductive material 777 may be conformally deposited into vertical openings 770 and fill the continuous horizontal openings up to the unetched portions of the oxide material 742, the first dielectric material 739, and the dielectric material 733. The conductive material 777 may be conformally deposited using a chemical vapor deposition (CVD) process, plasma enhanced CVD (PECVD), atomic layer deposition (ALD), or other suitable deposition process.

In some embodiments, the first conductive material, 777, may comprise one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc., and/or some other combination thereof. The first conductive material 777 entwined with the gate dielectric material may form horizontally oriented access lines opposing a channel region of the single crystalline silicon (Si) material (which also may be referred to a word lines).

FIG. 7C illustrates a cross sectional view, taken along cut-line C-C’ in FIG. 7A, showing another view of the semiconductor structure at this particular point in one ex ample semiconductor fabrication process of an embodiment of the present disclosure. The cross sectional view shown in FIG. 7C is illustrated extending in the second horizontal direction (D2) 705, left and right in the plane of the drawing sheet, along an axis of the repeating iterations of alternating layers of continuous horizontal openings and single crystalline silicon (Si) material 732.

In FIG. 7C, first dielectric material 739 is shown spaced along a second horizontal direction (D2) 705, extending into and out from the plane of the drawings sheet, for a three dimensional (3D) array of vertically oriented memory cells. At the left end of the drawing sheet is shown the repeating iterations of alternating layers of first dielectric material 739, separated by continuous horizontal openings in a first direction (D1) 709 filled with a first conductive material 777. The first conductive material 777 may be conformally deposited into vertical openings 770 and into the horizontal openings. At the right hand of the drawing sheet, the first dielectric material 739 may be seen, separating access device and storage node regions in the first direction (D1) 709.

FIG. 7D illustrates a cross sectional view, taken along cut-line D-D’ in FIG. 7A, showing another view of the semiconductor structure at this particular point in one example semiconductor fabrication process for forming vertical three dimensional (3D) memory arrays combinable with pitch interface layers, in accordance with a number of embodiments of the present disclosure. The cross sectional view shown in FIG. 7D is illustrated, right to left in the plane of the drawing sheet, extending in the first direction (D1) 709 along an axis of the repeating iterations of alternating layers of first dielectric material 739 and single crystalline silicon (Si) material 732 wrapped with a gate dielectric material 742. The gate dielectric material 742 may be conformally deposited fully around every surface of the single crystalline silicon (Si) material 732, to form gate all around (GAA) gate structures, at the channels of the access device regions. The first conductive material 777 may fill the spaces adjacent the bridged single crystalline silicon (Si) material 732. The single crystalline silicon (Si) material 732 may be surrounded by the first conductive material 777 formed on the gate dielectric material 742. The first conductive material 777 may be conformally deposited fully around every surface of the single crystalline silicon (Si) material 732, to form gate all around (GAA) gate structures, at the channels of the access device regions. In FIG. 7D, the first conductive material, 777 is shown filling in the space in the second horizontal openings left by the etched second dielectric material 733.

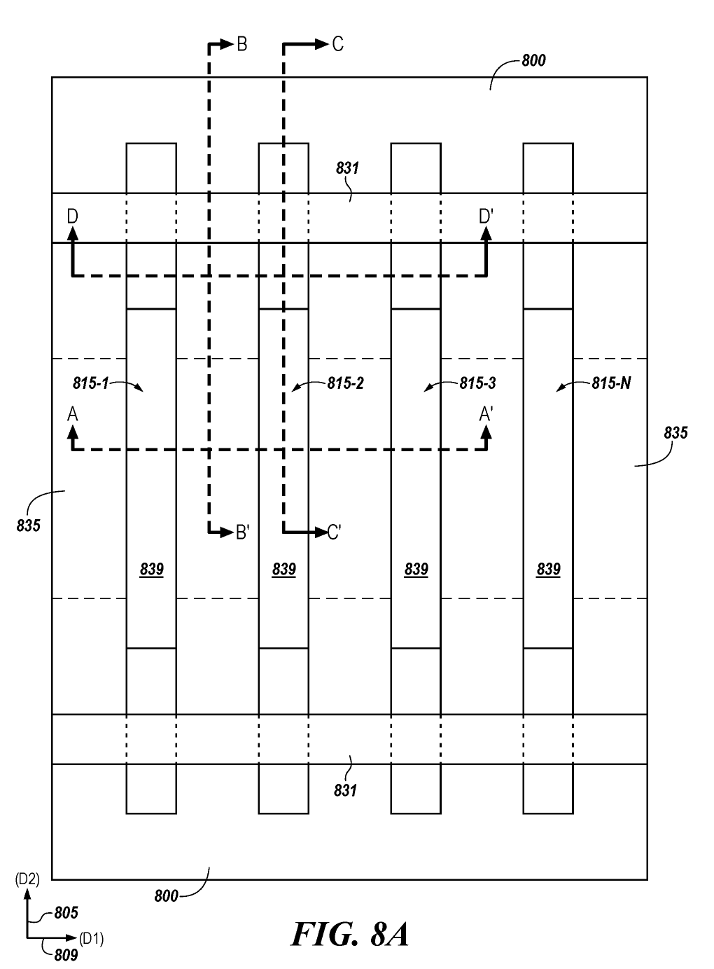

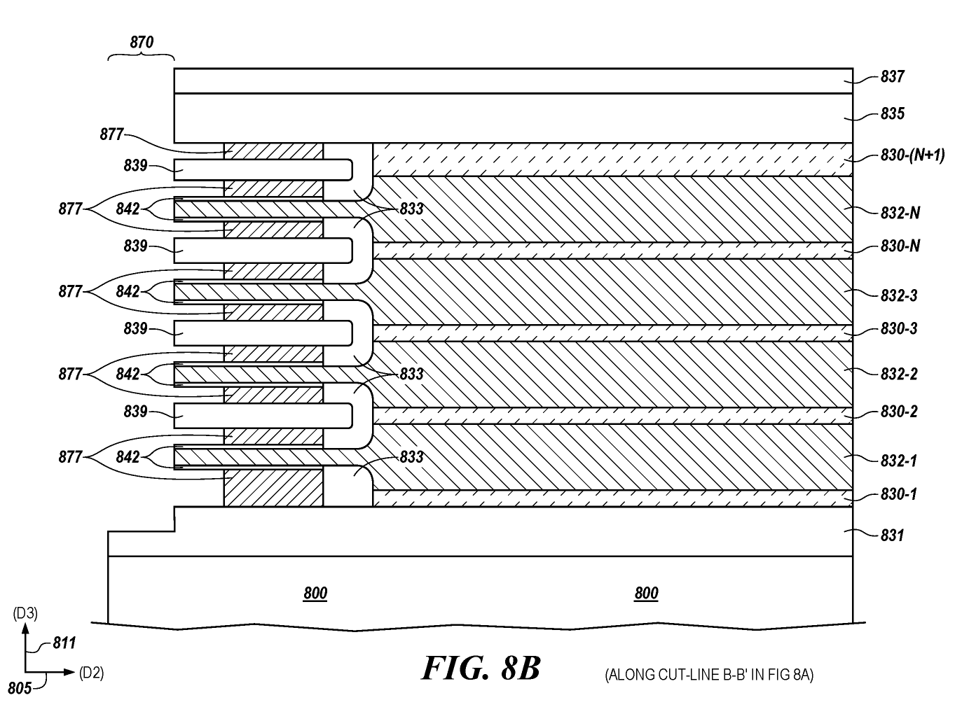

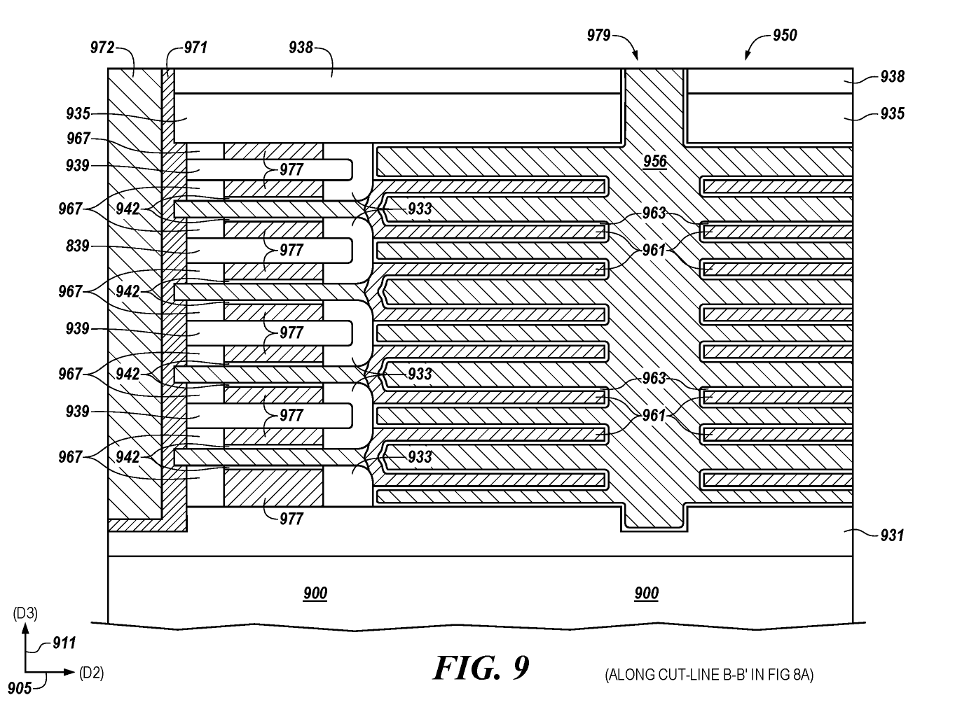

FIG. 8A illustrates an example method, at another stage of a semiconductor fabrication process, for forming vertical three dimensional (3D) memory arrays combinable with pitch interface layers, in accordance with a number of embodiments of the present disclosure. FIG. 8A is a top down view. FIG. 8B illustrates a cross sectional view taken along cut-line B-B’ in FIG. 8A. FIG. 8B is illustrated extending in the second horizontal direction (D2) 805, left and right along the plane of the drawing sheet, along an axis of the repeating iterations of alternating layers of the silicon germanium (SiGe) material 830 and the single crystalline silicon (Si) material 832.

A first conductive material 877 was deposited on the gate dielectric material and formed around the single crystalline silicon (Si) material 832, recessed back, to form gate all around (GAA) structure opposing channel regions of the single crystalline silicon (Si) material 832. The first conductive material 877, formed on the gate dielectric material 842, may be recessed and etched away from the second vertical opening 870. In some embodiments, the first conductive material 877 may be etched using an atomic layer etching (ALE) process. In some embodiments, the first conductive material 877 may be etched using an isotropic etch process. The first conductive material 877 may be selectively etched leaving the oxide material 842 covering the epitaxially grown, single crystalline silicon (Si) material 832 and the first dielectric material 839 intact. The first conductive material 877 may be selectively etched in the second direction, in the continuous horizontal openings, a third distance (DIST 3) in a range of twenty (20) to fifty (50) nanometers (nm) back from the first vertical opening 870. The first conductive material 877 may be selectively etched around the single crystalline silicon (Si) material 832 back into the continuous horizontal openings extending in the first horizontal direction.

FIG. 9 illustrates an example method, at another stage of a semiconductor fabrication process, for forming vertical three dimensional (3D) memory arrays combinable with pitch interface layers, in accordance with a number of embodiments of the present disclosure. The cross sectional view shown in FIG. 9 is illustrated extending in the second horizontal direction (D2) 905, left and right along the plane of the drawing sheet.

FIG. 9 illustrates an example embodiment of a vertical digit line formed by the combination of second conductive material 971 and third conductive material 972 formed within the first vertical openings (e.g., vertical openings 870 in FIG. 8). As shown in FIG. 9 a third dielectric material 967 has been deposited in the second vertical opening to fill the first horizontal openings from the recessed first conductive material 977 to the first vertical opening, and then is removed from the second vertical opening. In some embodiments, the third dielectric material may be a silicon carbide, silicon nitride, silicon oxide carbide, or other suitable dielectric.

As shown in the example embodiment of FIG. 9, a second conductive material 971 may be conformally formed in the second vertical opening. The second conductive material 971 may be formed from a conformal deposition of a highly doped polysilicon material 971. In one example, the dopant can include a high concentration n-type dopant. In a further example, the polysilicon may first be deposited and then a high concentration of n-type dopant may be implanted therein from the second conductive material 971. One example of forming the second conductive material 971 includes conformally depositing a highly phosphorus (P) doped (n+-type dopant) poly-silicon germanium (SiGe) material into the first vertical openings for the second conductive material 971.

a. As shown in the example embodiment of FIG. 9, a third conductive material 972 may be deposited into the first vertical opening on the second conductive material 971 to fill the vertical opening as shown in FIG. 9. In some embodiments, the third conductive material 972 may comprise one or more of a doped semiconductor material, e.g., doped silicon, doped germanium, etc., a conductive metal nitride, e.g., titanium nitride (TiN), tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc., and/or some other combination thereof. The third conductive material 972 electrically connected to the second conductive material 971 may be formed vertically adjacent first source/drain regions to horizontal access devices to form multi-layer vertical digit lines 971/972. According to embodiments the vertical digit lines can be electrically connected from the 3D DRAM array, e.g., 302 in FIG. 3B, to appropriate electrical connections, e.g., sense amplifiers (SAs), digit line multiplexers (DLMUXs), etc., located in a pitch interface layer, e.g. 303 in FIG. 3B, before further connection to a memory cell control circuitry, e.g., 301 in FIG. 3B. In some embodiments, the deposition of the second and the third conductive materials may be switched, or more than two multilayer and/or gradient digit lines (DLs) constructed.

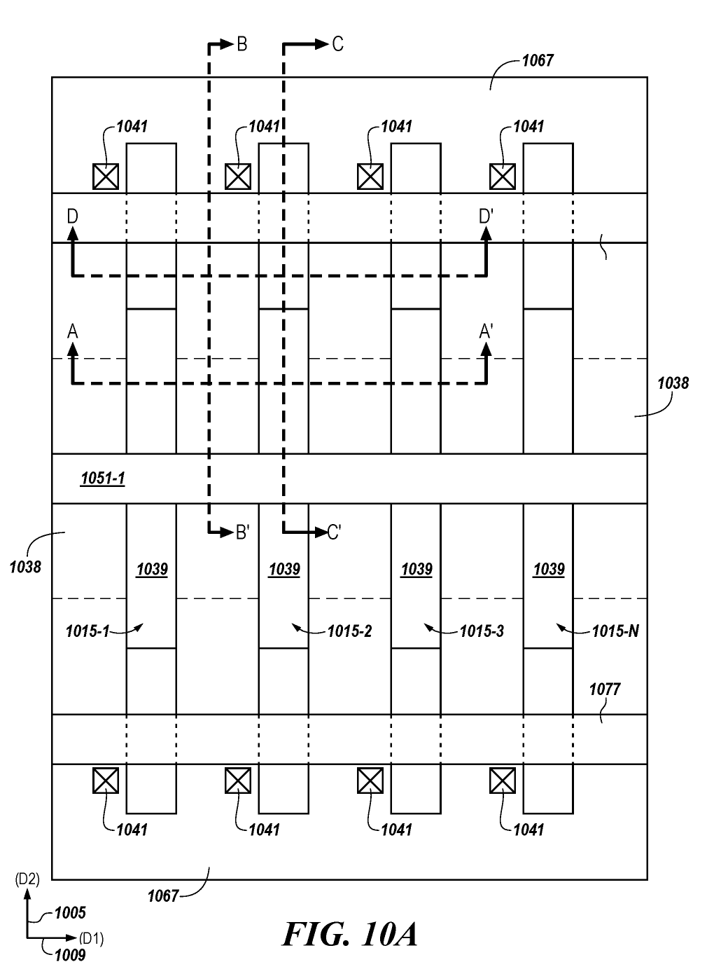

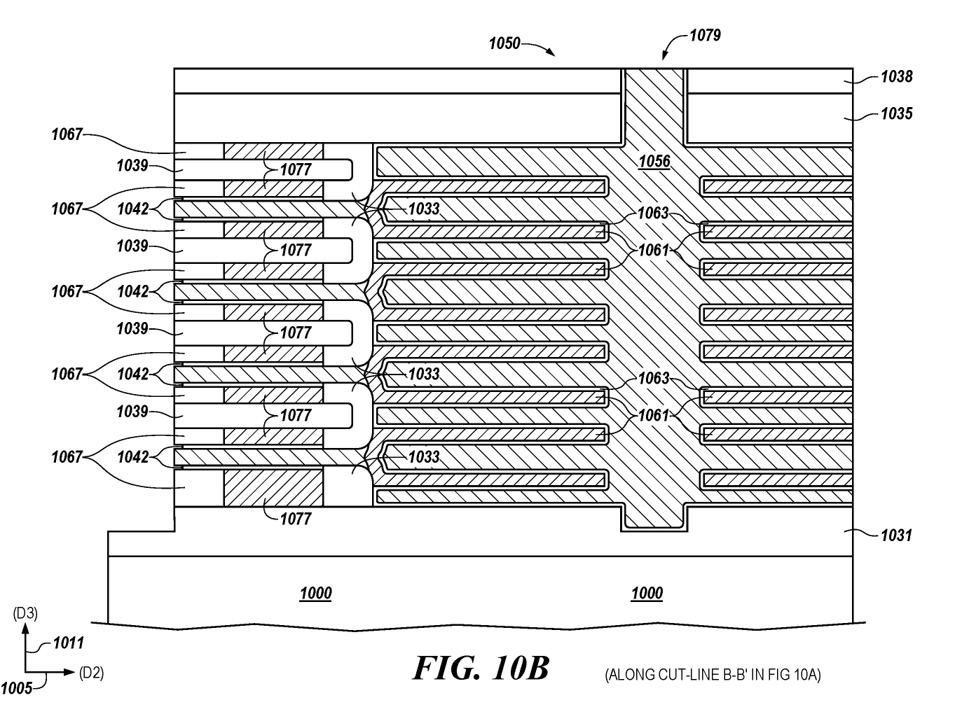

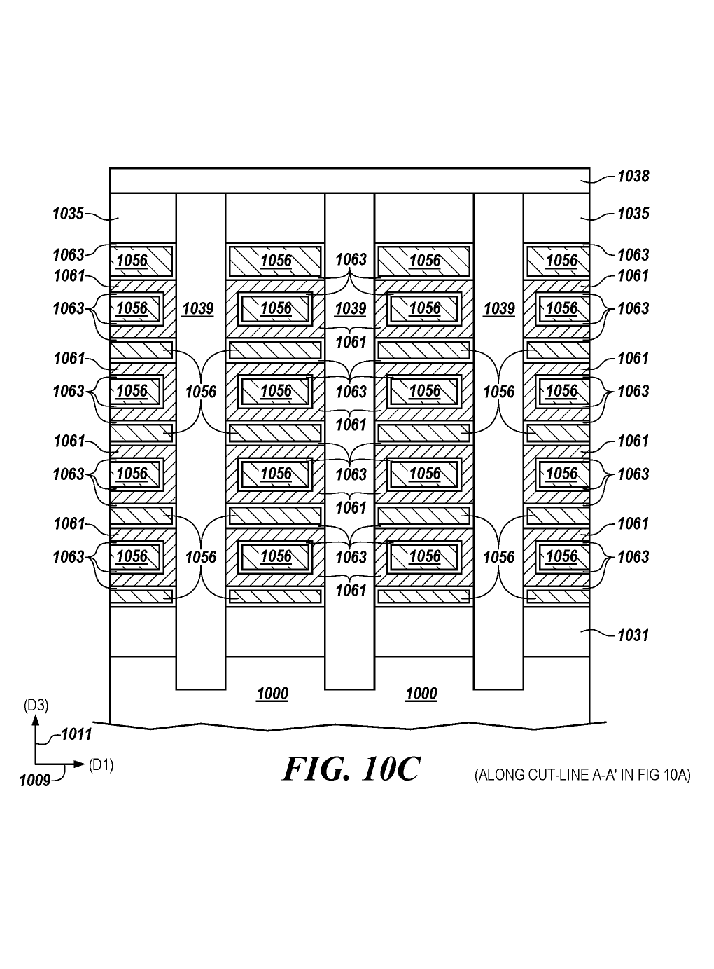

FIG. 10A illustrates an example method, at another stage of a semiconductor fabrication process, for forming vertical three dimensional (3D) memory arrays combinable with pitch interface layers, in accordance with a number of embodiments of the present disclosure. FIG. 10A is a top down view. As illustrated in FIG. 10A, a vertical opening 1051 can be formed in a storage node region 1050 through the vertical stack and extending predominantly in the first horizontal direction (D1) 1009. The vertical opening 1051 can be formed from one or more etchant processes to expose sidewalls in the repeating iterations of alternating layers of alternating silicon germanium (SiGe), 430-1, 430-2, . . ., 430-N layers and epitaxially grown, single crystalline silicon (Si) material, 432-1, 432-2, . . ., 432-N layers, shown in FIG. 4 in the vertical stack in order to form storage nodes.

FIG. 10B is a cross sectional view, taken along cut-line B-B’ in FIG. 10A, showing another view of the semiconductor structure at a particular time in the semiconductor fabrication process. In FIG. 10B, one or more etchant processes can be utilized to form the storage node region 1050. The storage node region 1050 can include storage nodes (e.g., horizontally oriented capacitor cells) having the first electrodes 1061, e.g., bottom electrodes to be electrically connected to second source/drain regions of horizontal access devices, and second electrodes 1056, e.g., top electrodes to be electrically connected to a common electrode plane such as a ground plane, separated from the first electrodes by a storage node dielectric material 1063.

According to embodiments the second electrodes, e.g., top electrodes, can be electrically connected from the 3D DRAM array, e.g., 302 in FIG. 3B, to appropriate electrical connections, e.g., power supply transistors 364 and CMOS logic 356, in a first portion of memory cell control circuitry components, through a pitch interface layer, e.g., 303 in FIG. 3B, join the memory cell control circuitry to the memory array in a face to face (F2F) orientation.

The storage nodes are shown formed in a third horizontal opening 1079, extending in second direction (D2) 1005, left and right in the plane of the drawing sheet, a third distance from the vertical opening formed in the vertical stack and along an axis of orientation of the horizontal access devices and horizontal storage nodes of the arrays of vertically stacked memory cells of the three-dimensional (3D) memory. In FIG. 10B, a neighboring, horizontal access line 1077 is illustrated adjacent the second dielectric material 1033, with a portion of the first conductive material 1077 located above the Si material 1032, and a portion of the first conductive material 1077 located below the Si material 1032 extending in a direction inward and outward from the plane and orientation of the drawing sheet.

FIG. 10C is a cross sectional view, taken along cut-line A-A’ in FIG. 10A, showing another view of the semiconductor structure at a particular time in the semiconductor fabrication process. The cross-sectional view shown in FIG. 10C is away from the plurality of separate, horizontal access lines 1077, and shows repeating iterations of alternating layers of second electrodes 1056 separated by horizontally oriented capacitor cells having first electrodes 1061, e.g., bottom cell contact electrodes, cell dielectric material 1063, and top, common node electrodes, on a semiconductor substrate 1000 to form the vertical stack. In the example embodiment of FIG. 10C, the first electrodes 1061, e.g., bottom electrodes to be electrically connected to source/drain regions of horizontal access devices, and second electrodes 1056 are illustrated separated by a cell dielectric material 1063 extending into and out of the plane of the drawing sheet in second direction (D2) and along an axis of orientation of the horizontal access devices and horizontal storage nodes of the arrays of vertically stacked memory cells of the 3D memory. In FIG. 10C, the first dielectric material 1039 is shown separating the space between neighboring horizontally oriented access devices and horizontally oriented storage nodes.

FIG. 11 is a block diagram of an apparatus in the form of a computing system 1100 including a memory device 1103 including vertical three dimensional (3D) memory arrays on a memory array combined with pitch interface layers, using a pitch interface layer, including a memory cell control component, to connect memory cell control circuitry to the memory array in face to face (F2F) orientation, in accordance with a number of embodiments of the present disclosure. In some embodiments, the memory cell control circuitry includes a first portion of memory cell control circuitry components and the pitch interface layer includes a second portion of memory cell control circuitry components. The second portion of memory cell control circuitry components is configured to distribute array efficiency, wafer usage density, and reduce overlay constraints. The second portion of the memory cell control circuitry components may have a second power consumption usage, different from a first power consumption usage of the first portion of memory cell control circuitry components on the memory cell control circuitry. As used herein, a memory device 1103, a memory array 1110, and/or a host 1102, for example, might also be separately considered an “apparatus.” According to embodiments, the memory device 1103 may comprise at least one memory array 1110 with a memory cell formed having a digit line and body contact, according to the embodiments described herein.

In this example, system 1100 includes a host 1102 electrically connected to memory device 1103 via an interface 1104. The computing system 1100 can be a personal laptop computer, a desktop computer, a digital camera, a mobile telephone, a memory card reader, or an Internet-of-Things (IoT) enabled device, among various other types of systems. Host 1102 can include a number of processing resources (e.g., one or more processors, microprocessors, or some other type of controlling circuitry) capable of accessing memory 1103. The system 1100 can include separate integrated circuits, or both the host 1102 and the memory device 1103 can be on the same integrated circuit. For example, the host 1102 may be a system controller of a memory system comprising multiple memory devices 1103, with the system controller 1105 providing access to the respective memory devices 1103 by another processing resource such as a central processing unit (CPU).

In the example shown in FIG. 11, the host 1102 is responsible for executing an operating system (OS) and/or various applications (e.g., processes) that can be loaded thereto (e.g., from memory device 1103 via controller 1105). The OS and/or various applications can be loaded from the memory device 1103 by providing access commands from the host 1102 to the memory device 1103 to access the data comprising the OS and/or the various applications. The host 1102 can also access data utilized by the OS and/or various applications by providing access commands to the memory device 1103 to retrieve said data utilized in the execution of the OS and/or the various applications.

For clarity, the system 1100 has been simplified to focus on features with particular relevance to the present disclosure. The memory array 1110 can be a DRAM array comprising at least one memory cell having a digit line and body contact formed according to the techniques described herein. For example, the memory array 1110 can be an unshielded DL 4F2 array such as a 3D-DRAM memory array. The array 1110 can comprise memory cells arranged in rows coupled by word lines (which may be referred to herein as access lines or select lines) and columns coupled by digit lines (which may be referred to herein as sense lines or data lines). Although a single array 1110 is shown in FIG. 11, embodiments are not so limited. For instance, memory device 1103 may include a number of arrays 1110 (e.g., a number of banks of DRAM cells).

The memory device 1103 includes address circuitry 1106 to latch address signals provided over an interface 1104. The interface can include, for example, a physical interface employing a suitable protocol (e.g., a data bus, an address bus, and a command bus, or a combined data/address/command bus). Such protocol may be custom or proprietary, or the interface 1104 may employ a standardized protocol, such as Peripheral Component Interconnect Express (PCIe), Gen-Z, CCIX, or the like. Address signals are received and decoded by a row decoder 1108 and a column decoder 1112 to access the memory array 1110. Data can be read from memory array 1110 by sensing voltage and/or current changes on the sense lines using sensing circuitry 1111. The sensing circuitry 1111 can comprise, for example, sense amplifiers that can read and latch a page (e.g., row) of data from the memory array 1110. The I/O circuitry 1107 can be used for bi-directional data communication with the host 1102 over the interface 1104. The read/write circuitry 1113 is used to write data to the memory array 1110 or read data from the memory array 1110. As an example, the circuitry 1113 can comprise various drivers, latch circuitry, etc.

Control circuitry 1105 decodes signals provided by the host 1102. The signals can be commands provided by the host 1102. These signals can include chip enable signals, write enable signals, and address latch signals that are used to control operations performed on the memory array 1110, including data read operations, data write operations, and data erase operations. In various embodiments, the control circuitry 1105 is responsible for executing instructions from the host 1102. The control circuitry 1105 can comprise a state machine, a sequencer, and/or some other type of control circuitry, which may be implemented in the form of hardware, firmware, or software, or any combination of the three. In some examples, the host 1102 can be a controller external to the memory device 1103. For example, the host 1102 can be a memory controller which is electrically connected to a processing resource of a computing device.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

The figures herein follow a numbering convention in which the first digit or digits correspond to the drawing figure number and the remaining digits identify an element or component in the drawing. Similar (e.g., the same) elements or components between different figures may be identified by the use of similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause and effect relationship). An element coupled between two elements can be between the two elements and electrically connected to each of the two elements.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” another element, the particular element can cover the other element, can be over the other element or lateral to the other element and/or can be in direct physical contact with the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. A device, comprising:
memory cell control circuitry having complementary metal oxide semiconductor (CMOS) components;
a memory array having a three-dimensional (3D) dynamic random access memory (DRAM) cell structure; and
a pitch interface layer, including a memory cell control component, electrically connecting the memory cell control circuitry to the memory array such that the memory cell control circuity and the memory array are in a face to face (F2F) orientation.

2. The device of claim 1, wherein the pitch interface layer is positioned vertically on the memory array in between the memory cell control circuitry and the memory array and makes an electrical connection between an electrical node of the CMOS components and an electrical node of the memory array.

3. The device of claim 1, wherein the pitch interface layer is a portion of a pitch wafer, and the pitch wafer is configured to electrically connect, in a wafer bonding process, a memory cell control circuitry wafer having the CMOS components and a memory wafer having the memory array.

4. The device of claim 1, the pitch interface layer, including a memory cell control component, having digit line multiplexers (DLMUX) and sub-wordline drivers for the 3D DRAM array formed thereon, electrically connecting the 3D DRAM array to the memory cell control circuitry.

5. The device of claim 1, the pitch interface layer, including a memory cell control component, having sense amplifiers (SAs) and sub-wordline drivers for the 3D DRAM array formed thereon, electrically connecting the 3D DRAM array to the memory cell control circuitry.

6. The device of claim 1, wherein the pitch interface layer, including a memory cell control component, electrically connects the memory cell control circuitry to the memory array using a hybrid copper (Cu) to copper (Cu)/copper to oxide bonds with the memory cell control circuitry and the memory array.

7. The device of claim 1, further comprising:
the memory cell control circuitry having a first portion of memory cell control circuitry components, including input/output (I/O) connections; and
the pitch interface layer, including a memory cell control component, having a second portion of memory cell control circuitry components configured to distribute array efficiency, wafer usage density, and reduce overlay constraints.

8. The device of claim 1, the 3D DRAM array having horizontally oriented, vertically stacked memory cells in a plurality of levels, the array, comprising:
horizontally oriented access devices at each level having first source/drain regions and second source/drain regions separated by channel regions, and horizontally oriented access lines forming gates separated from the channel regions by gate dielectric material; and
horizontally oriented storage nodes at each level electrically connected to the second source/drain regions of the horizontally oriented access devices; and
vertically oriented digit lines electrically connected to the first source/drain regions of the horizontally oriented access devices and to digit line demultiplexers (DLMUXs) in the pitch interface layer.

9. A device, comprising:
memory cell control circuitry having a first portion of memory cell control circuitry components, including input/output (I/O) connections;
a memory array having a dynamic random access memory (DRAM) cell structure of horizontally oriented, vertically stacked memory cells in a plurality of levels; and
a pitch interface layer having a second portion of memory cell control circuitry components and electrically connecting the memory cell control circuitry to the memory array in a face to face (F2F) orientation, the second portion configured to distribute array efficiency (AE), to increase wafer usage density, and/or to reduce wafer to wafer electrical connection constraints.

10. The device of claim 9, wherein the second portion of memory cell control circuitry array logic in the pitch interface layer, comprises:
digit line multiplexers (DLMUXs) and sub-wordline drivers electrically connected to the DRAM array on the memory array and electrically connected to the first portion of memory cell control circuitry components on the memory cell control circuitry.

11. The device of claim 9, wherein the second portion of memory cell control circuitry components in the pitch interface layer, comprises:
sense amplifiers (SAs) and sub-wordline drivers electrically connected to the DRAM array on the memory array and electrically connected to the first portion of memory cell control circuitry components.

12. The device of claim 9, wherein:
the memory cell control circuitry having complementary metal oxide semiconductor (CMOS) logic; and
wherein the 3D DRAM array further comprises:
horizontally oriented access devices having first source/drain regions and second source/drain regions separated by channel regions, and horizontally oriented access lines forming gates separated from the channel regions by gate dielectric material;
horizontally oriented storage nodes electrically electrically connected to the second source/drain regions of the horizontally oriented access devices; and
vertically oriented digit lines connected to the first source/drain regions of the horizontally oriented access devices and to the pitch interface layer.

13. The device of claim 12, wherein the vertically oriented digit lines comprise epitaxially formed vertical digit lines connected to the first source/drain regions of the horizontally oriented access devices.

14. The device of claim 9, wherein the pitch interface layer, including a memory cell control component, electrically connects the memory cell control circuitry to the memory array using a hybrid copper (Cu) to copper (Cu) and copper to oxide bonds.

15. The device of claim 9, wherein the horizontally oriented access lines forming gates form gate all around structures (GAA) separated from the channel regions by gate dielectric material.

16. The device of claim 9, wherein the horizontally oriented storage nodes comprise double sided capacitors.

17. A device, comprising:
memory cell control circuitry having a first portion of memory cell control circuitry components, including input/output (I/O) connections;
a memory array having a three-dimensional (3D) dynamic random access memory (DRAM) cell structure, the array further comprising:
horizontally oriented access devices having first source/drain regions and second source/drain regions separated by channel regions, and horizontally oriented access lines forming gates on a gate dielectric at the channel regions; and
horizontally oriented storage nodes electrically connected to the second source/drain regions of the horizontally oriented access devices; and
a pitch interface layer having a second portion of memory cell control circuitry components and electrically connecting the memory cell control circuitry to the memory array in a face to face (F2F) orientation using hybrid copper (Cu) to copper (Cu) and copper to oxide bonds.

18. The device of claim 17, wherein the second portion of memory cell control circuitry components in the pitch interface layer, comprises:
digit line multiplexers (DLMUXs) and sub-wordline drivers electrically connected to the DRAM array on the memory array and electrically connected to the first portion of memory cell control circuitry components.

19. The device of claim 18, further, comprising:
the memory cell control circuitry having complementary metal oxide semiconductor (CMOS) logic; and
the 3D DRAM array having vertically oriented digit lines connected to the first source/drain regions of the horizontally oriented access devices and to the DLMUXs in the pitch interface layer.

20. The device of claim 19, wherein the vertically oriented digit lines comprise epitaxially formed vertical digit lines.

21. The device of claim 17, wherein the second portion of memory cell control cell components in the pitch interface layer, comprises:
sense amplifiers (SAs) and sub-wordline drivers electrically connected to the DRAM array and electrically connected to the first portion of memory cell control circuitry components.

22. The device of claim 17, wherein the horizontally oriented access lines form gate all around (GAA) structures on the gate dielectric material at the channel regions.

23. The device of claim 17, wherein the horizontally oriented storage nodes comprise double-sided capacitors.
